(19) United States
(12) Patent Application Publication
(10) Pub. No.: US 2003/0172527 A1
(43) Pub. Date: Sep. 18, 2003

(54) Automated trim processing system

(76) Inventors: Anton Kitai, Ottawa (CA); Paul Andrew Labelle, Smith Falls (CA); Jeremy Philip Mitchell, Ottawa (CA); Andreas Mank, Ottawa (CA); Robert Glenn Parker, Ottawa (CA); Ian Miller, Ottawa (CA)

Correspondence Address: ANTONELLI, TERRY, STOUT & KRAUS, LLP, Suite 1800, 1300 North Seventeenth Street, Arlington, VA, 22209, US

(21) Appl. No.: 10/097,613

(22) Filed: Mar. 15, 2002

(51) Int. Cl. H05K 3/02; H01R 43/20; G05F 1/00

(52) U.S. Cl. 29/847; 29/593; 29/747; 29/832

(57) ABSTRACT

An automated method for trimming a circuit element disposed on a substrate includes transmitting a first signal to move a substrate, having a circuit element disposed thereon, to a trimming location. A second signal is transmitted to emit a light beam, with the substrate at the trimming location, to trim the circuit element.

### TECHNICAL FIELD

The present invention relates to trimming elements formed on a panel or other work piece. More particularly the present invention relates to trimming elements, such as resistors, capacitors or other passive circuit elements, embedded in a layer of a multi-layer work piece, such as a Printed Circuit Board (PCB).

### BACKGROUND ART

Material processing is used to adjust the performance of electronic elements by removing or otherwise affecting a portion of the material of the electronic element to change the electrical characteristics thereof. It is known to change the electrical properties of passive and some active electronic elements by removing material therefrom. Methods of removing material include applying laser energy heat for vaporizing a portion of the material, applying laser energy heat for ablative removal of the material and applying laser energy energy to affect a photochemical reaction for removing and or otherwise altering an electrical performance characteristic of the material. It is well known that the relative of these three processes depends on the energy density and wavelength of the laser, and the properties of the material illuminated by the laser.

Lasers are used to perform all of these material-processing techniques. Laser material processing is routinely performed using a position and power controlled laser beam that is directed to scan over a desired region of the material for processing. These techniques are used to process individual passive electronic elements such as resistors, capacitors and inductors, as well as to process electrical elements in microchips, e.g. for memory chip repair and/or for trimming electrical elements formed onto silicon or other crystalline substrates.

In particular, a laser beam is directed over a region of the electrical element to remove or trim material from the element. The trimming may affect the electrical performance of the element by reducing the volume of electrical material in the element or to by altering a path of electron flow through the material, e.g. by creating a longer resistive path or even by creating an open circuit by completely removing a conductive path between two elements.

It is well know in the manufacturing of precision electrical resistors to laser trim each resistor to adjust its resistive value to fall within a desired range. It is also known to measure the resistive value during the laser trimming process and to continue to trim the resistor until the resistive value is acceptable.

FIGS. 1A & 1B depict a conventional precision resistor manufacturing process wherein a resistor panel 100 comprises a ceramic substrate 110 having a plurality of precision resistor elements 120 formed thereon by a printing, screening, growing or any other resistor forming process. The resistor panel 100 may also include conductive portions formed thereon including conductive leads (not shown) attached to each resistor 120 for providing an electrical connection to the resistor element. Conductive measurement passive elements 130 may also be provided for probing the resistor element 120 to measure its resistance value.

FIG. 1B depicts an enlarged resistor element 120 having conductive measurement passive elements 130 attached thereto for providing a convenient resistance measuring position for place measurement probes 140 in electrical contact with the resistor element 120 for measuring its resistance value. A measurement circuit 150 is connected to the probes 140 and applies a measurement voltage across the resistor element 120. It is customary that the probes 140 measure the resistance value during the trimming process.

According to conventional precision resistor manufacturing methods, it is desired that each of the resistor elements 120 formed on the ceramic substrate 110 have substantially the same resistance value within a narrow tolerance range. However, each resistor element 120, as applied to or formed onto the ceramic substrate 110 may have a resistance value that falls outside of the desired range due to uncontrollable aspects of forming the resistive elements onto the substrate. Accordingly it is known to trim each resistor using a laser-trimming device to adjust the resistance value, if needed, such that all of the resistor elements have a resistance value that is within the desired range. To trim each resistor element 120, the probes 140 are electrically contacted onto the measurement passive elements 130 and the initial resistance value is measured. A laser beam is then directed onto the resistor element being probed to make a trim cut which cuts through the resistor material to the ceramic substrate. The cut resistor has an increased electrical resistance as compared to the uncut resistor.

Various resistor trimming cuts are known, including a double plunge cut shown in FIG. 2A and an L cut shown in FIG. 2B. In each of these cuts it is desirable to adjust the resistance value without locally restricting the current flow so much that the region of the resistor around the trim cut is excessively heated by ohmic losses during normal operation of the finished circuit. Accordingly, the cuts are made in a central region of the resistors without cutting more than about half way across the resistor width, W. In FIG. 2C, a typical capacitor cut is shown wherein a corner of the capacitor is isolated from the remaining element to adjust the area of one of the conductive layers.

Once the trimming is complete, the panel 100 is diced up into sections with one resistive element 120 on each section and the resistive elements are sold to other electronics manufactures to be incorporated into electrical circuits usually as surface mounted elements. Accordingly it is known in the prior art to manufacture individual resistors, which are trimmed before being incorporated into an electrical circuit or installed onto a PCB panel. These resistors may be surface mounted onto printed circuit boards (PCB's) such as computer mother boards, cell phone controllers, and the like, or the resistors may be used in transducers, testers, controllers or any other type of electrical device where a pre-measured pre-calibrated resistor may be required.

Examples of resistor trimming devices currently available for laser trimming resistors include the GSI LUMONICS W670 Thick Film Laser Trim System and W678 Thin Film Laser Trim Systems each manufactured and distributed by the assignee of the present invention.

In other examples of laser trimming, it is known to trim individual elements such as chip resistors, resistor networks and integrated passive elements that are incorporated into an integrated circuit formed, for example, on a silicon substrate. As described above, individual elements of the chip may be probed to measure an electrical characteristic of the element and laser trimmed to adjust the electrical characteristic as required. The finished tested and trimmed chips may then be sold for incorporation into another device, e.g. surface mounted onto a PCB, or the chip itself may comprise a special purpose device such as a transducer. One example of a chip element laser trimmer currently available is the GSI LUMONICS W770 Chip Element Trim System, manufactured and distributed by the assignee of the present invention.

It is also known to trim elements after an element has been surface mounted onto a PCB or otherwise incorporated into an electrical circuit. In this case, a completed and functional device may be probed to measure an electrical response to an electrical input stimuli and one of the circuit elements of the electrical circuit may be laser trimmed while the circuit is active, to change the circuit performance according to a desired circuit response.

Other electronic elements such as capacitors and inductors have also been trimmed using a laser to remove or otherwise affect a material that can change the capacitance or inductance of the element. It is known to trim individual passive elements such as resistors, capacitors and inductors to achieve a desired resistance, capacitance or inductance. It is also known to trim passive elements in a passive network of elements for example to adjust the resistance of a pair of resistors connected in parallel or in series by trimming just one of the resistor elements.

As shown in FIG. 3, historically, pre-manufactured trimmed electronic elements and even trimmed integrated circuits mounted on silicon chips have been installed onto the surface of a prefabricated PCB blank. A section of a finished PCB 160 of the prior art is shown in FIG. 3. Passive electronic elements 170 and 180, such as pre-trimmed resistors, capacitors, inductors or chips, are attached to a PCB blank and interconnected with other circuit elements via conductive layers 190 which provide predetermined conductive paths between surface mounted elements. Each conductive layer is separated by a dielectric layer 200 to electrically isolate the conductive layers.

Passive electronic elements may electrically contact just the top conductive layer 190, as shown for the element 170 (called surface mount components), or an component may be mounted in one or more holes drilled completely through the printed circuit board (called through hole components), possibly connected to several conductive layers 190 depending on the individual circuit design. In this latter case, the element 180 includes conductive leads 210 that are inserted into through holes 220 drilled or otherwise formed in the PCB blank prior to mounting the element 180. In any case, the elements are attached and electrically contacted to conductive layer(s) by soldering.

Thus according to the prior art, a finished PCB includes one or more conductive layers and one or more dielectric layers. The conductive layers are generally etched or otherwise formed into a pattern of conductive paths that interconnect to form electrical circuits. Via holes are predrilled through the one or more conductive and dielectric layers to allow a surface mounted element to form an electrical contact with one or more conductive layers. Thereafter, passive or active electronic elements of the circuits such as resistors, capacitors, inductors, chips, transistors, amplifiers, diodes, and the like, are surface mounted onto the PCB blank and soldered to contact one or more of the desired conductive layers. In many cases, the electrical elements are pre-trimmed to provide a specific electrical performance. However, in some cases, a surface mounted element may be trimmed after installation onto the PCB blank.

According to newly developed procedures for fabricating finished PCB's, some passive elements are being formed directly onto the conductive and or dielectric layers of a PCB blank such as is shown in FIG. 4. FIG. 4 depicts one example of a partially fabricated PCB panel 240 having a dielectric layer 250 and a plurality of conductive paths 260 formed onto the dielectric layer 250 by conventional means.

As shown, the substantially same circuit pattern 270 is repeated six times over the panel such that six separate circuits may be formed on the single panel 240. After completion, including the mounting of any surface mounted elements, the panel 240 may be diced up into six separate PCB's. Alternately, the panel 240 may comprise one large circuit element.

In the present example, a plurality of passive resistors 280 are formed directly onto the panel 240 by printing, painting or otherwise applying a resistive paste or liquid between selected conductive paths 260 of the circuit 270. Each resistor is in direct contact with the dielectric layer 250 and interconnects at least two isolated conductive paths 260. As an alternative process, a sheet of resistive or insulating material backed with a conductive layer is laminated as a continuous layer on the circuit board, and then the paterns are etched in the conductive/resistive or conductive/insulating structure to form resistors or capacitors. Both the printing and etching techniques for forming embedded passive elements are discussed in greater detail following a discussion of the present limitations of embeding passive elements in printed circuit boards.

All of the passive resistors 280 may be applied simultaneously such as through screen or template or they may be applied in several steps. After application, the resistive paste or liquid is cured by baking or another curing process to provide a finished resistor. In subsequent fabrication steps, one or more dialectic and conductive layers may be applied over the layer including over the cured resistors just applied, as shown in FIG. 4. Moreover, additional resistors may be formed directly onto subsequently formed layers of the PCB blank. In a completed PCB, formed by the process, numerous passive resistors may be formed onto each layer of the PCB such that a large number of resistors are embedded within the PCB panel 240.

A significant benefit of the method of embedding passive elements into the PCB blank is that each embedded passive element eliminates a corresponding surface mounted passive element thereby providing more space on the surface for mounting other elements, or reducing the overall area of the finished circuit board. In addition, the cost of fabricating embedded resistors is lower than the cost of separately fabricating and then surface mounting surface mount resistors. The above process and benefits also apply to other embedded passive elements such as capacitors and inductors.

A problem with the use of embedded passive elements is that the electrical characteristics of the elements are difficult to control and predict because of variables in the fabrication process.

Accordingly, heretofore, embedded passive elements have been restricted in use to circuits that can tolerate a wide variation in resistor or other passive element values and manufacturers have been forced to use surface mounted passive elements whenever a narrow range of electrical performance is required of a particular circuit element. This has limited the use of embedded passive printed circuit boards in many critical performance systems.

Embedded elements are usually placed on layers close to the core material because this part of the panel experiences less distortion during the build-up or lamination process. The initial placement of these elements takes place in the earlier stages of production of a PCB at which point the elements are on the top surface of the panel. After all of the passive elements are printed and cured, or etched, another layer, e.g. a copper or dielectric layer, is laminated over the layer to embed the passive elements.

Conventional systems used for trimming resistors are designed to process substrates up to about 8 inches by 8 inches, depending on the application. In addition, these substrates are typically manufactured of alumina ceramic and are temperature stable, rigid and free from distortion.

There is now a need to perform such trimming on larger substrate sizes, such as 18 by 24, or 24 by 36 inch panels. Furthermore, these substrates will typically be printed circuit boards, that are flexible, affected by changes in temperature and prone to distortion in multiple lamination steps.

Accordingly, a need exist for an improved technique for trimming of resistors, or other passive circuit elements, embedded within a relatively large multi-layer PCB panel.

Automation for handling of the typical alumina substrates that are the usual base for discrete passive elements and hybrid circuits is a well developed area. Machines for trimming these types of components often include handlers that feed individual substrates from a stack into the trimming section of the machine before they are moved out to an unloading area. In these machines there is no allowance for significant substrate flexibility or distortion either in handling or automated vision alignment of the parts prior to the trimming process.

Within the printed circuit board industry, typical panel sizes range from 12 inches by 18 inches, to 18 inches by 24 inches to 24 inches by 30 inches. These panels can be very flexible, and because the conductive layers can be fragile, so called slip-sheets are often placed between panels when they are stacked. These slip-sheets are usually thin sheets of plastic or paper. A variety of automated handling equipment is used to transport circuit boards, and to insert and remove slip-sheets during conventional printed circuit board manufacturing. These handlers include combinations of conveyors, and lifting/shuttling equipment, typically using vacuum suction cups to pick up individual PCB panels or slip-sheets.

### OBJECTIVES OF THE INVENTION

Accordingly, it is an object of the present invention to provide a system and method for trimming passive elements formed directly onto PCB panels.

It is a further object of the present invention to provide a trimming system and methods for trimming PCB panels having a variety of sizes and shapes.

It is another objective of the present invention to provide mechanical systems and methods for storing, moving and receiving PCB panels, having circuit elements formed thereon, without damaging the circuit elements formed and to provide mechanical systems that eliminate manual handling of the PCB panels.

Additional objects, advantages, novel features of the present invention will become apparent to those skilled in the art from this disclosure, including the following detailed description, as well as by practice of the invention. While the invention is described below with reference to preferred embodiment(s), it should be understood that the invention is not limited thereto. Those of ordinary skill in the art having access to the teachings herein will recognize additional implementations, modifications, and embodiments, as well as other fields of use, which are within the scope of the invention as disclosed and claimed herein and with respect to which the invention could be of significant utility.

### SUMMARY OF THE INVENTION

In accordance with the invention, an automated system for trimming a circuit element disposed on a substrate, includes a moveable pick-up device, such as a gantry, and an emitter, such as a laser beam generator and a focusing lens. The substrate could, for example, be a panel having circuit elements, such resistors, capacitors or other type elements. The moveable pick-up device picks-up the substrate with the circuit element disposed thereon, and moves the substrate to a trimming location. Preferably, the substrate is picked-up from a first holder, which may be in the form of a cassette, at which it is stored prior to trimming of the circuit element. If desired, the first holder can also store a slip sheet on top of the substrate and the moveable pick-up device can be further configured to pick-up the slip sheet from the first holder. The emitter emits a light beam, with the substrate at the trimming location, to trim the circuit element.

Beneficially, after the circuit element has been trimmed, the moveable pick-up device also picks-up the substrate at the trimming location, and moves the substrate to a storage location.

According to another aspect of the invention, a second holder stores the substrate subsequent to trimming the circuit element. If so, the moveable pick-up device can be further configured to move a picked-up slip sheet to the second holder. In such a case, the substrate is moved to the trimming location after the picked-up slip sheet is moved to the second holder.

To enhance operational efficiency, the emitter may also be configured to emit the light beam, with another substrate, having another circuit element disposed thereon, at the trimming location, and with moveable pick-up device moving the slip sheet to the second holder. With the slip sheet moved to the second holder, the moveable pick-up device may be further configured to pick-up the trimmed second substrate from the trimming location and to move the picked-up second substrate to the second holder. The moveable pick-up device may be still further configured to pick-up the first substrate from the first holder and to move the picked-up first substrate to the trimming location, after the second substrate is picked-up from the trimming location and moved to the second holder.

According to other aspects of the invention, the system includes a moveable stage to adjust a positional relationship between the substrate at the trimming location and a path of the emitted light, such that the circuit element is in a field of view prior to emitting the light beam. For example, the stage may move the emitter or the substrate to adjust the positional relationship. Additionally or alternatively, the emitter may be configured to adjust the path of the emitted light beam with the substrate at the trimming location, to trim the circuit element, for example using a desired type of cut.

According to yet another aspect of the invention, the system may include a probe, which may be in a form commonly referred to as a probe card, to measure an electrical characteristic of the trimmed circuit element with the substrate at the trimming location. The measurement may be performed either during and/or after the trimming.

Advantageously, the moveable pick-up device moves the substrate, with the trimmed circuit element, from the trimming location to one holder if the measured electrical characteristic is within a threshold and to another holder, such as a reject tray, if the measured electrical characteristic is outside the threshold.

In a preferred embodiment, the system includes a housing for first and second cassette holders that allows both the cassette holders to be removed from a same side of the housing. The housing may, for example, include a hinged door on that side of the housing so that at least one of the cassette holders is accessible for removal by opening the hinged door. The side of the housing may beneficially be the front side, with the first and the second cassette holders are positioned at the same elevation and disposed side by side when viewed from the front side of the housing. In such a case, either a single hinged door or two hinged doors on the front side of the housing may be provided. If two hinged doors are provided, the first holder is accessed for removal by opening one hinged door, and the second holder is accessed for removal by opening the other hinged door.

According to still other aspects of the invention, the trimming location is also accessible from the same side of the housing. With such accessibility, a substrate, having a circuit element disposed thereon, can be manually placed at the trimming location and/or manually removed from the trimming location after completion of the trimming.

According to another preferred embodiment of the invention, the first and the second holders are removable from different sides of the housing. For example, the different sides may include the front and rear sides of the housing. In such a case, the first cassette holder may be at the same elevation as the second cassette holder, and disposed adjacent to the second cassette holder and proximate to the front side of the housing, while the second cassette holder is disposed proximate to the rear side of the housing.

### BRIEF DESCRIPTION OF DRAWINGS

FIG. 1A depicts a resistor panel having ceramic substrate having untrimmed resistor elements formed thereon for trimming by a conventional laser-trimming device.

FIG. 1B depicts a single untrimmed resistor element including measurement pads and a resistance-measuring device for measuring the untrimmed resistance.

FIG. 2A depicts a conventional double plunge laser-trimming cut.

FIG. 2B depicts a conventional “L” cut laser trimming cut.

FIG. 2C depicts a conventional laser-trimming cut in a capacitor plate.

FIG. 3 depicts a conventional PCB having surface mounted electronic components mounted thereon.

FIG. 4 depicts untrimmed passive resistor elements conventionally formed on a circuit board panel.

FIG. 5 depicts a schematic diagram of a system for trimming untrimmed passive circuit elements formed onto a PCB panel or workpiece.

FIG. 6 depicts a probe card and probe measurement circuit according to the invention.

FIG. 7 depicts a. stack of panels with slip-sheets in a panel holder

FIGS. 8a and 8b is a first embodiment of the handler assembly shown in FIG. 5 according to the present invention

FIG. 9 depicts a more detailed depiction of the panel pick-up head shown in FIG. 8b.

FIG. 10 depicts a second embodiment of the handler assembly shown in FIG. 5 according to the present invention.

FIG. 11 depicts a third embodiment of the handler assembly shown in FIG. 5 according to the present invention.

FIG. 12 depicts a fourth embodiment of the handler assembly shown in FIG. 5 according to the present invention.

FIG. 13 depicts a fifth embodiment of the handler assembly shown in FIG. 5 according to the present invention.

FIG. 14 depicts a sixth embodiment of the handler assembly shown in FIG. 5 according to the present invention.

FIG. 15 depicts a seventh embodiment of the handler assembly shown in FIG. 5 according to the present invention.

FIG. 16a depicts an eighth embodiment of the handler assembly shown in FIG. 5 according to the present invention.

FIG. 16b depicts a ninth embodiment of the handler assembly shown in FIG. 5 according to the present invention.

FIG. 17 depicts a tenth embodiment of the handler assembly shown in FIG. 5 according to the present invention.

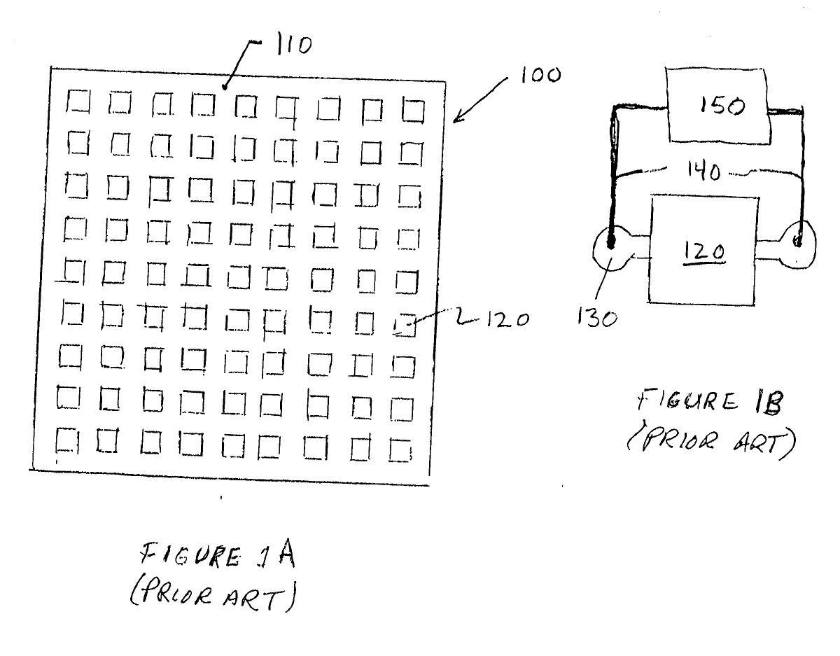

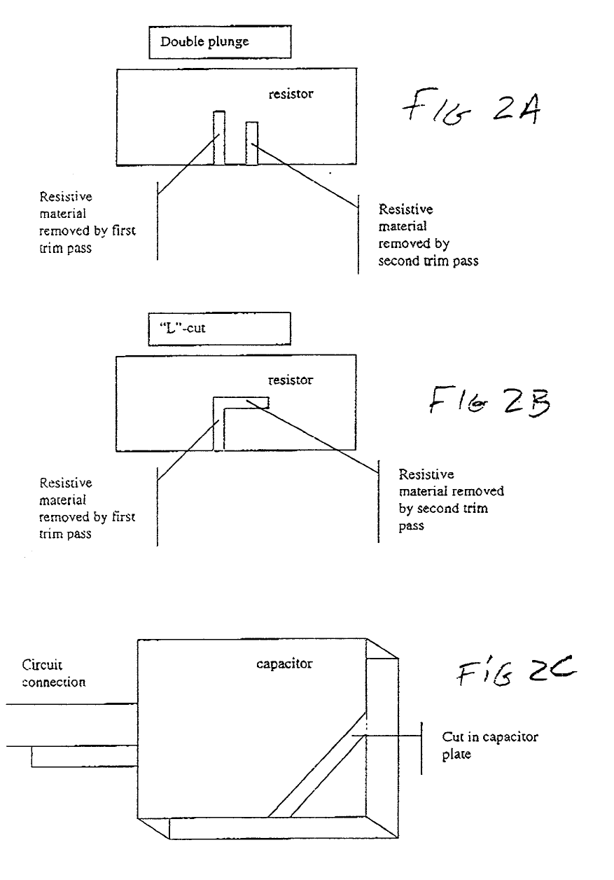

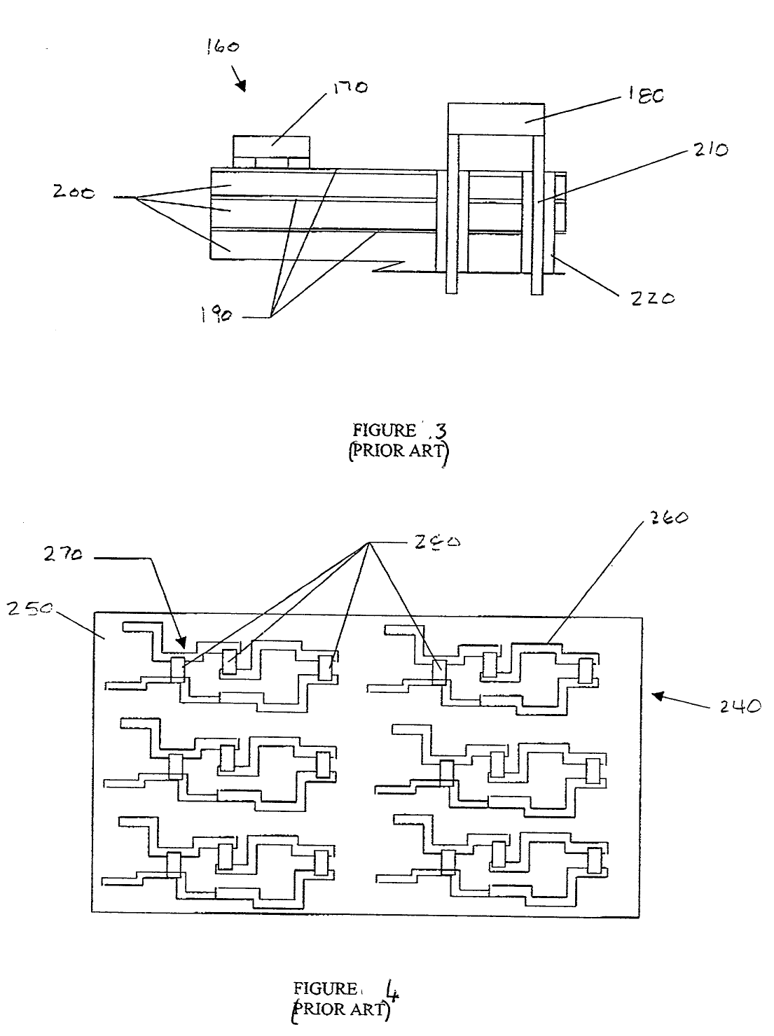

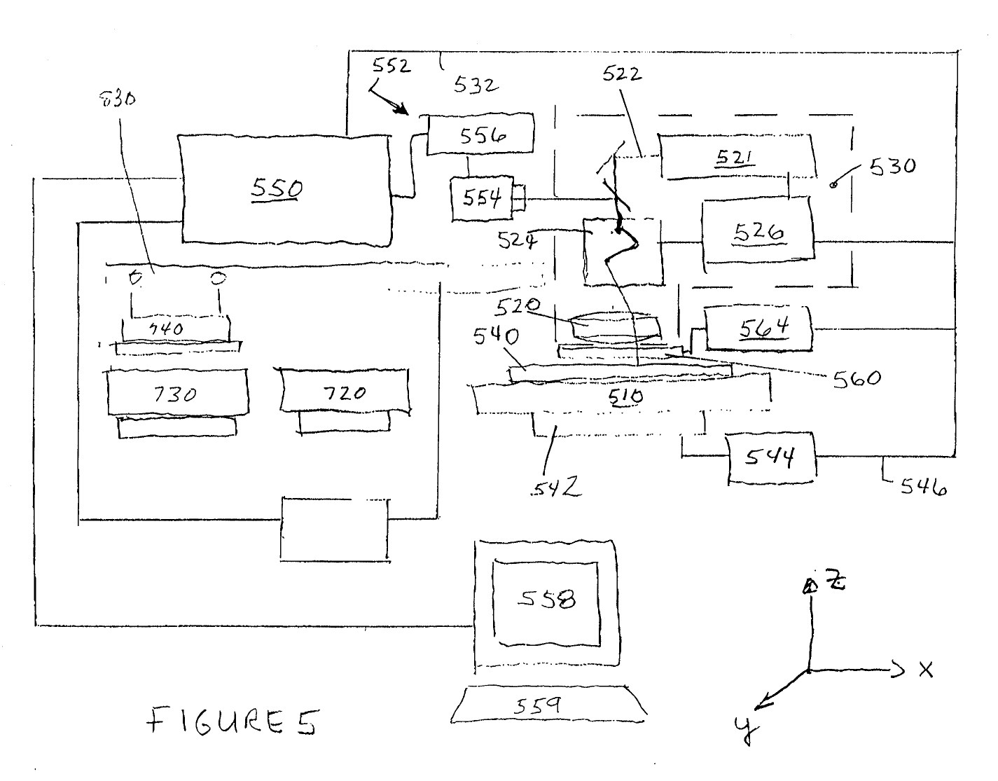

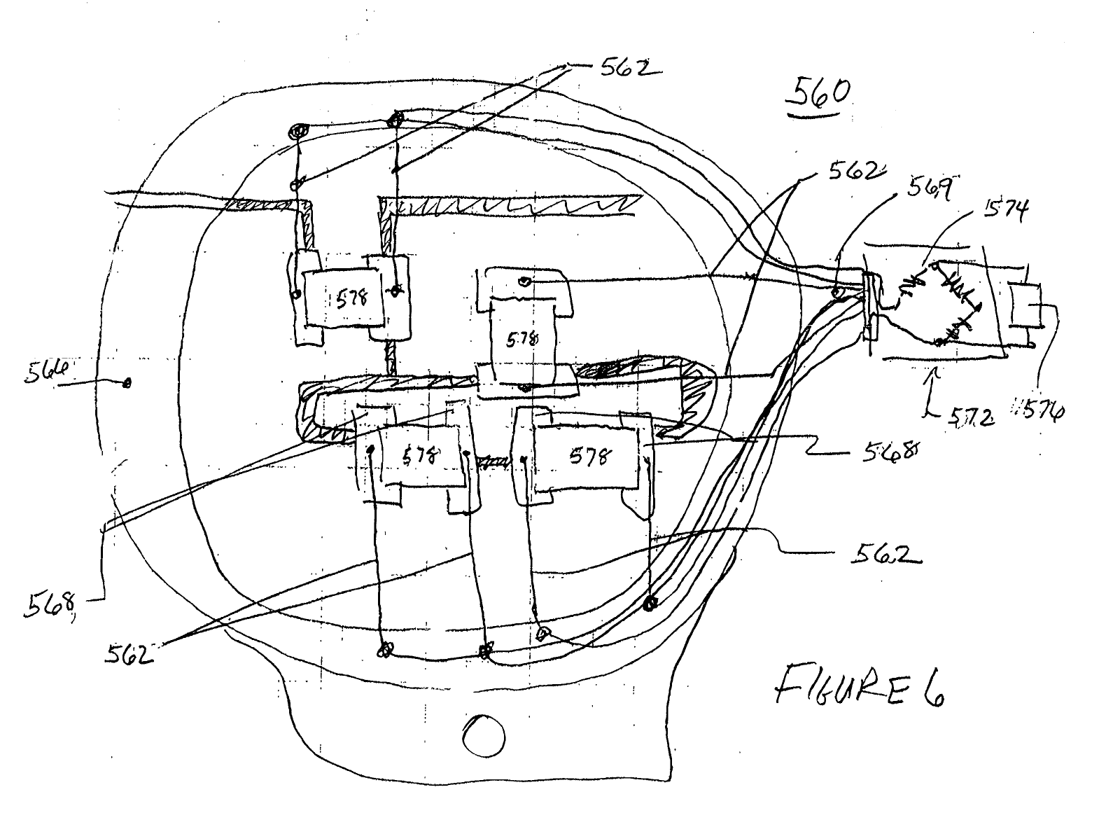

### BEST MODE FOR CARRYING OUT THE INVENTION

Trimming System Overview

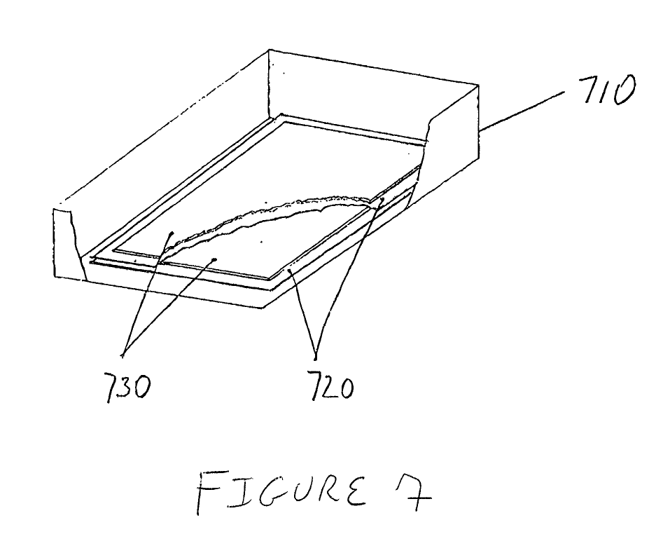

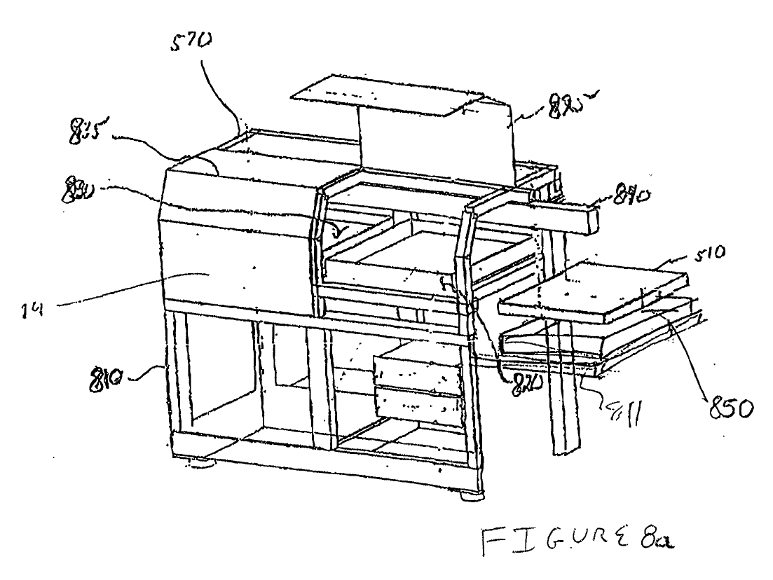

FIG. 5 depicts a system 500 for trimming untrimmed circuit elements formed onto a PCB panel, similar to those depicted in FIG. 4, or onto any panel or work piece. A panel or work piece herein refers to a substrate for forming finished circuit boards therefrom and includes at least one dielectric layer or substrate, at least one conductive layer or substrate and at least one untrimmed circuit element formed thereon. In general the dielectric layer may be formed from an epoxy resin having fiberglass filler or other know dielectric substrates used in PCB fabrication. One example of a dielectric layer is the material FR4 available from Du Pont. The conductive layer may comprise a copper layer that is laminated or otherwise deposited contiguous with the dielectric layer. In general the dielectric layer has a thickness in the range of about 0.25-1.5 mm and the conductive layer is thinner, usually less than about 0.1 mm. The untrimmed circuit element may comprise at least one resistor, capacitor or inductor formed contiguous with one of the dielectric or conductive layers or both. The untrimmed element may also comprise a portion of the dielectric layer or a portion of the conductive layer, as is the case for an untrimmed embedded capacitor.

A panel includes at least one conductive path formed by the conductive layer thereof and the conductive path may form a portion of an electronic circuit to be fabricated in a finished circuit board fabricated from the PCB panel. The at least one conductive path may comprise portions of a plurality of conductive layers formed onto a single panel, such as in a multi-layer PCB. A panel may be used as a substrate for forming a plurality of substantially identical circuits, formed in a repeated pattern on the panel as shown in FIG. 4, or a panel may be used as a substrate for forming a single circuit e.g. a computer mother board, or a panel may be used as a substrate for forming a plurality of different circuits formed in a pattern thereon. A panel size may be the same size as the finished circuit board fabricated therefrom or a panel may be subsequently diced up to form a plurality of smaller sized finished circuit boards. Although panels may be fabricated and trimmed in any size, it is desirable and customary to form panels in a rectangular or square shape having dimensions of from about 10×15 inches (25.4×38.1 mm) up to about 28×36 inches, (71.1×91.4 mm).

Laser Subsystem

As shown in FIG. 5, the trimming system 500 includes a laser subsystem 530, outlined in fantom, for directing a laser beam 522 onto a surface of a panel 540 for trimming an untrimmed element formed thereon. The laser subsystem 530 includes a laser 521 and a beam-directing device 524 capable of directing the laser beam 522 over a selected region of the panel 540. The laser subsystem 530 also includes a lens 520 positioned in the path of the laser beam 522, between the laser 521 and the panel 540, for focusing the laser beam 522 to a desired size and energy density at the surface to be trimmed. The field of the lens 520 may range from about 1.0 inch in diameter up to about 8 inches in diameter but a field view of that allows the laser beam 522 to be directed over about a 2 inch×2 inch to a 4 inch×4 inch region of the panel 540 is preferred in the present embodiment. Accordingly, the field of view of the laser subsystem 530 is defined by an aperture of the lens 520 and allows a focused beam to address any selected position within the field of view of the lens for processing untrimmed elements within a region of the panel that is positioned in the lens field of view.

The laser subsystem 530 may also include one or more laser subsystem controllers 526 for controlling the position, velocity and power output of the focused laser beam 522 during trimming and during periods when the laser is not trimming. In general, the lens field of view is considerably smaller than the panel size such that all of the elements within the lens field of view are trimmed without moving the panel 540 and then the panel 540 is moved with respect to the lens field of view to position an untrimmed portion of the panel 540 in the lens field of view for trimming. Preferably, the lens 520 is a telecentric lens and the beam-deflecting device 524 is positioned substantially at a focal plane of the lens 520 so that the laser beam 522 impinges substantially normal or perpendicular to the surface to be trimmed over the entire field of view of the lens.

Accordingly, the laser subsystem 530 emits a trimming beam that is focused substantially at a surface of an untrimmed circuit element disposed onto the panel 540 and has sufficient power to precisely remove or otherwise process the material of the untrimmed circuit element in a controlled manner. The position of the laser beam 522 emitted by the laser subsystem 530 can be changed to impinge on untrimmed elements anywhere within the field of view of the lens 520. The motion and modulation of the laser beam 522 is controlled by laser subsystem control signals issued by the laser subsystem controller 526 and the desired positions and motion characteristics of the laser are provided by signals received from a system controller 550 over a connection 532. The system controller 550 controls the operation of the entire trimming system.

The controllable laser subsystem 530 may be of any type, but preferably includes a laser 521 that emits an energy beam at a wavelength that is compatible with the type of trimming or laser processing being performed. For example, if a dielectric material is primarily being trimmed, a CO2 laser emitting at a wavelength of approximately 10 um may be most suitable and if a conductive layer is being trimmed, a solid state laser emitting at a wavelength of approximately 1.06 um may be the best selection and if the trimming is photochemical process the laser wavelength may be visible or ultraviolet light such approximately 533 nm and shorter. In the preferred embodiment, a ND YAG laser emitting at approximately 1.06 um is used for trimming resistor materials.

The beam-directing device 524 may comprise any scanning device for scanning a laser beam over a two dimensional region. In the present example, a pair of orthogonally mounted galvanometer mirror scanners, not shown, is provided between the laser 521 and the lens 520. Each galvanometer mirror scanner includes an angular position transducer for tracking the angular position of the mirrors and a servo driver for controlling the angular rotation of each deflecting mirror to for directing the laser beam 522 to a desired position. In the present example, the laser subsystem controller 526 includes all driving controls for the laser and the beam deflector. However, these controls may be incorporated into the system controller 550 or further separated into additional controllers.

Panel Motion

The trimming system 500 also includes an X-Y stage 542, upon which is mounted a panel fixture 510 which supports the panel 540, sometimes referred to as the work piece, on which untrimmed circuit elements, similar to those shown in FIG. 4, have been deposited on the panel 540 by any material deposition means. The panel fixture 510 is movable by the X-Y stage 542 in the X and Y directions, in accordance with stage control signals issued by a stage controller 544, in communication with the system controller 550 over the link 546. The stage 510 could be of the type controlled by a stepper or linear motor drive, or a ballscrew, belt or band drive system driven by a rotary motor, or by other know drives, and provides very precise X-Y positioning of the panel 540 with respect to a reference position which may be the center of the field of view of the lens 520. By moving the panel fixture 510, different areas of the panel 540 can be positioned within the field of view of the lens 520. Alternatively, the panel fixture 510 may be held in a stationary position during trimming. In this case, the entire laser subsystem 530 may be mounted onto an X-Y stage as described above. In this case, the laser subsystem 530 can be positioned over different portions of the panel 510 to place the lens field of view over a region to be trimmed.

Vision System

In order to view the panel 540, a computer vision system, generally referred to by reference numeral 552, is provided. The vision system 552 comprises a video camera 554, and a video frame buffer and video image processing electronics, 556, which may be incorporated within, or in communication with, the system controller 550. The vision system 552 is positioned to view the panel 540 through the lens 520 such that the video camera 554 captures images of the lens field of view. The images, which may be captured at rates of about 30 frames per second to continuously up date the image of the field of view, may be displayed on a video display device 558 for viewing by an operator, or the images may be captured, stored and analyzed by the video image processing electronics 556 or the electronic controller 550. The vision system may be used to measure or otherwise determine a location of an element in the camera field of view and the in combination with the system controller 550 be used to determine a location of any element or feature on the panel 540 according to known algorithms.

The vision system 552 may be used to select and or inspect circuit elements on the panel 540 or to capture images of one or more alignment targets or fiducials, e.g. on the panel 540 or on the X-Y Stage 510 to provide information about the position of the panel 540. Images of the targets may be used to determine a position or angular orientation of the panel 540 with respect to a system reference position or orientation. In addition, video images of other alignment targets and or circuit elements may be used to determine a position of an object within the lens field of view and to direct the laser beam 522 in accordance with the position of an object as determined by the vision system 552. The vision system 552 may also be used to detect if the correct PCB panel has been loaded onto panel fixture 510, if the untrimmed elements appear to be properly applied onto the panel 540 and if a trimmed elements meet predefined trim criteria such as whether the trim cut is properly positioned with respect to any edges or other features of the circuit element being trimmed. In addition, the vision system 522 may be used to determine a position or condition of a measurement probe, which is described below. Accordingly, an error condition detected by the vision system 522 may be communicated to the system controller 550 where a logical decision can be made to either correct the error or to take some other automatic action in response to the error condition, including stopping the trim operation. The system 500 also includes one or more operator input devices such as a keyboard 559, mouse or control panel.

Probing and Measuring

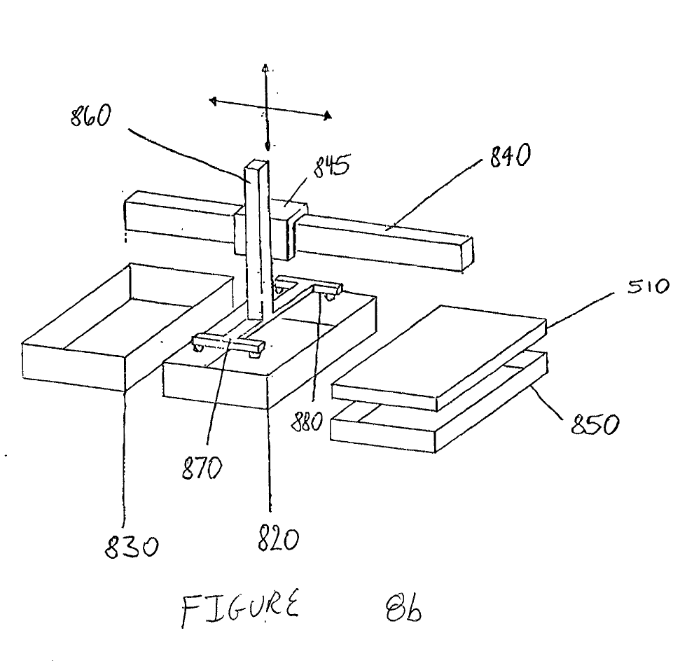

To perform the necessary trimming of the untrimmed circuit elements, formed on the work piece during the fabrication process, the controller 550 issues control signals to the X-Y stage controller 544 directing the X-Y stage 542 to first position one or more circuits located on the panel 540 within the field of view of the lens 520. The trimming system 500 may also include, but does not require in all applications, an electrical measurement subsystem that can be used to probe the circuits before, during, and/or after trimming. A probe card 560, shown in detail in FIG. 6 is one of several types of probing modules that may be connected to the measurement system. Other probing options include flying probe assemblies, non-contact capacitive or inductive probes, or other known electrical probing techniques. In the case of use of a probe card, the probe card 560 is positioned over the portion of the panel 540 to be trimmed and includes probes 562 for measuring circuit element during trimming and provides a clear path for the laser beam 522 to trim the circuit elements in the field of view of the lens 520. The probe card 560 is supported for vertical movement parallel to the Z-axis shown in FIG. 5. The probe card 560 further includes a probe controller 564, which is in communication with the system controller 550. Prior to trimming elements, the controller 550 sends control signals to the probe controller 564 to lower the measurement probes 652 onto the panel 540 thereby placing the measurement probes 562 into contact with measurement points for measuring an electrical characteristic of one or more circuit elements. The probe card 560 is lifted away from the panel 540 during period of no measurement, e.g. when the panel 540 is to be moved by the X-Y stages 542.

As shown in FIG. 6, the probe card 560 includes multiple sets of circuit element measurement probes 562 which may comprise flexible conductive elements supported by a probe support ring 566 and cantilevered from the probe support ring 566 to a position over a set of circuit element measurement pads 568 of a circuit element to be measured. The probe set may include two or more probes. Each set of probes 562 includes probe wire leads 569 leading out of the support ring 566 to a measurement circuit 572. The measurement circuit 572 may comprise a resistor bridge 574 and a voltage source 576, or other measurement circuit specific to the requirements of the pertinent electrical characteristics of the circuit being measured. Each set of probe leads 569 are switchably connected to the measurement circuit 572 such that each untrimmed or trimmed circuit element 578 can be addressed and measured as long as the measurement probes are in contact with the measurement pads thereof. The measurement circuit 572 provides and output signal for each measured electrical characteristic of the circuit element being measured and sends the output signal to the probe controller 564 or to the system controller 550. Alternately, all of the probes leads 556 may be simultaneously connected with the measurement circuit 572.

In general, each element to be trimmed that is within the field of view of the lens 520 will have a measurement probe set 562 associated therewith. All of the probe sets are simultaneously lowered into contact with the measurement pads 568, or a designated measurement area for measuring the circuit element 578. In the case of probes designed for mechanical contact, the probes may be forced into contact with the measurement pads 568 to obtain an acceptable electrical contact for measuring an electrical characteristic of the element 578.

Trimming Sequence

In a typical operational sequence, the system controller 550 will issue stage control signals to direct the X-Y stages 542 to move in X and Y directions required to position a selected portion of the panel 540 under the lens field of view. This step will usually include determining an actual position and orientation of the panel 540 on the fixture 510, using the vision system, so that the system controller 550 has a reference position and orientation of the PCB panel. Once the actual position of the panel 540 is known, the system controller 550 will position one or more circuits within the field of view of the lens 520 for trimming the untrimmed circuit elements 578 that fall within the lens field of view. The system controller 550 will also issue probe control signals directing the probe card 560 to contact the work piece with the probes 562. The system controller 550 will also issue a command to make an initial measurement of one or more circuit elements 578, to be trimmed, and to save the measured values in a memory associated with the system controller 550 or the probe controller 564. The system controller 550 will then issue laser module control signals directing the laser beam delivery module 530 to first emit a laser light beam 522 along a first path to make one or more trim operations on a first of the untrimmed circuit elements 578 within the field of view, to then emit the laser light beam along a second path to make one or more trim operations on a second of the untrimmed circuit elements within the field of view, and to continue changing the path of the laser light beam until all of the other untrimmed circuit elements 587 within the field of view of the lens 520 are trimmed. Meanwhile, the probes 562 will stay in electrical contact with measurement pads 568 such that the electrical characteristic of the element being trimmed may be actively measured during trimming and again after trimming is complete. It will be recognized that any of the measurement phases may be omitted if not required for the application. It will also be recognized that the trimming may be performed in multiple phases. That is, all untrimmed circuit elements 578 within a field of view of the lens 520 may first be subjected to a rough trimming and then, without further movement of the panel fixture 510, be subjected to a fine trimming by the laser beam delivery assembly 530. Moreover, it will be recognized that more than one measurement circuit 572 may be provided for measuring any of resistance, capacitance or inductance and that the untrimmed circuit elements 578 may have a plurality of desired resistance, capacitance an inductance target values. In addition it will be recognized that a plurality of probe cards 560 may also be sequentially or simultaneously positioned over the field of view of the lens 520 to probe different circuit elements 578. This may be especially true if the circuit elements 578 are densely distributed and more than one probe card 560 may be used to probe different groups of circuit element 578.

When all of the elements within the field of view of the lens are trimmed to the desired values, the probe card 560 is raised along the Z-axis and held in a park position. If not all untrimmed circuit elements 578 on the panel 540 have been trimmed, the system controller 550 issues stage control signals directing movement of the panel fixture 510 to locate the next untrimmed area of the of the panel 540, having a different circuit or circuits, within the field of view of the lens 520 for trimming. This process is repeated until all of the untrimmed circuit elements 578 on the panel 540 have been trimmed, or until a desired subset of circuits numbering less than the total number of circuits on the panel have been trimmed. If all of the desired untrimmed circuit elements 578 on the panel have been trimmed, the controller 550 issues control signals to either stop the system 500 for manual removal of the panel 540 or to mechanically remove the trimmed panel 540 from the panel fixture 510 using an automatic panel handler, and to load a new untrimmed panel 540 onto the panel fixture 510.

Thus, a panel 540 can be moved by the X-Y stages 542 to position any selected portion of the panel 540 within the field of view of the lens 520 and beneath the probe card 560 for measurement and trimming of each untrimmed element 578, until all of the untrimmed circuit elements 578 on the panel 540 are trimmed to provide trimmed circuit elements. A controller may store the measured circuit element values of every untrimmed and trimmed circuit element 578 on each panel 540 in a memory and the measured values may be used to maintain statistical records for improving the trimming process and to predict the type of trimming that may be required on subsequent panels 540. Moreover, a previously trimmed panel may be built up with subsequent panel layers, e.g. another dielectric layer and another conductive layer may be laminated over or otherwise deposited onto a previously trimmed panel layer and new conductive paths formed thereon. In addition, another layer of untrimmed passive elements 578 may be applied or deposited over the newly applied dielectric and conductive layers to provide a new layer of untrimmed circuit elements 578 on a previously trimmed panel 540. The new layer of circuit elements 578 may also be trimmed in the manner described above and the process may be repeated for even further layers of untrimmed circuit elements 578 applied over even further PCB layers.

In other situations, the panel 540 may have untrimmed passive elements 578 deposited on opposing sides of the panel 540. In this situation, the panel 540 will be passed through the trimming system 500 two times so that each of the opposing panel sides may be trimmed in a separate operation. In this case the panel 540 may be removed from the panel fixture 510 and, either manually turned over or mechanically turned over by an automatic panel handler for further trimming. In another scenario a plurality of panels 540 may be trimmed on a first side in a first sequence of trimming steps and then trimmed on an opposing side in second sequence of trimming steps. Use of an automated panel side flipper within the panel handling assembly is possible, and is described below. In this case a different probe card 560 may be installed for each of the opposing panel sides to probe different elements with different element locations. In another scenario, the panel may have a high density of circuit elements 578 for trimming and the trimming may be performed using two steps such that a plurality of panels are first trimmed in sequence using a first probe card 560 and then each of the panels is trimmed a second time, again in sequence, using a different probe card 560 for probing different areas of the panel. It will be recognized that there may be many reasons for passing each panel 540 through the trimming system 500 more than one time.

Panel Handling

In order to improve the throughput of trimming large numbers of panels 540 and further in view of a desire to mechanically handle the panels in an automatic manner, with a minimum of manual intervention, the trim system 500 also advantageously includes one or more automatic panel holders handlers and manipulators described below.

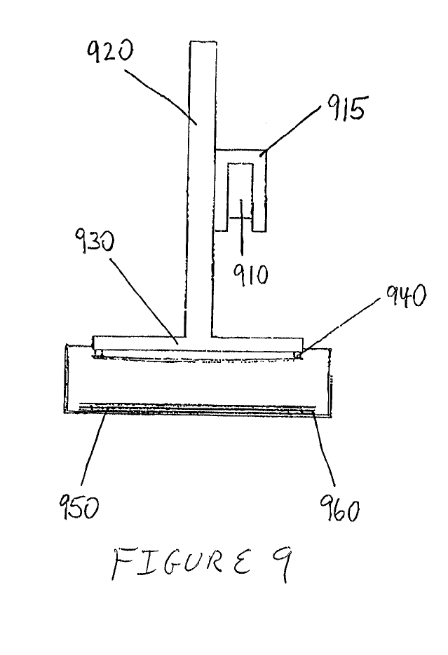

Panels which contain circuits composed at least partially of untrimmed circuit elements and trimmed circuit elements are sensitive to surface damage resulting from contact with other surfaces and or objects. FIG. 7, depicts a plurality of panels 730 stacked one above the other in a panel holder 710. The panel holder 710 may comprise any cassette, tray or rack that stores a plurality of panels in a stack and that can be used to transport a stack of panels to and from the trimming system 500. The stack of panels 730 are stored one above the other with the surface to be trimmed facing up. To protect the panels 730 a layer of softer protective material or slip-sheet 720, is usually interleafed between each of the panels 730 in the stack.

Additionally, panels 730 which contain circuits composed at least partially of untrimmed circuit elements and trimmed circuit elements may be sensitive to surface damage resulting from contact with the panel fixture 510 during processing. Accordingly, the fixture 510 includes a suitably protecting surface layer to protect the panels mounted thereon during the trimming operation. Suitable surfaces include layers with a paper, plastic, or other soft material composition. The method for clamping the panel on the panel fixture during trimming may comprise applying a vacuum through apertures passing through panel contact surfaces of the panel fixture 510. In this case, the protective layer on the panel fixture surface may porous so that air may be drawn therethrough to secure the panel onto the fixture 510, or a pattern of perforations through the protective layer may be provided for the air to be drawn through.

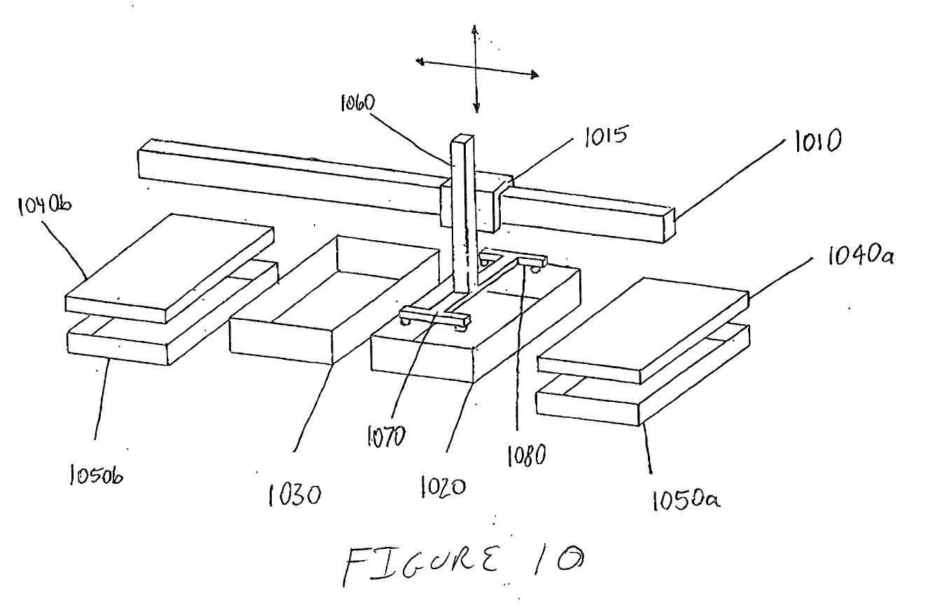

FIGS. 8a and 8b depict a preferred embodiment of a panel handler assembly 570, which is also shown schematically in FIG. 5. Also depicted in FIG. 8 is the panel fixture 510 positioned in a panel loading and unloading position. The panel loading and unloading position is achieved by commanding the X-Y stages to move the panel fixture 510 toward the panel handler assembly 570 such that the fixture 510 is accessible for loading or unloading a panel. As shown, the handler assembly 570 includes a support frame 810 for providing structural support for storing a plurality of panels within the panel handler 570. The frame 810 supports one or more panel holders 710, shown in FIG. 7, in a manner that provides unrestricted access by an operator for loading or unloading panels directly or for loading and unloading panel holders 710. As stated above, the panel holders 710 may comprise any cassette, tray or rack capable of receiving a plurality of panel stacked one above the other. In addition, the panel holder 710 may be completely removable from the panel handler 570 or may be movably supported by the frame 810 such that the holders may be pulled partially out the handler 570 and cantilevered from the frame 810 so that an operator can load or unload stacks of plates into the plate handler 570.

In the preferred embodiment, a first panel holder 820 is provided which can be easily completely removed from the handler assembly 570, filled with untrimmed panels and then easily reinstalled back into the handler assembly 570 when the panels loaded therein are required for a trimming job. The first panel holder 820 is supported by the frame 810 adjacent to the loading and unloading position of the panel fixture 510 and substantially at the same height off the floor as the panel fixture 510. The frame 810 also supports a second panel holder 830 immediately adjacent to the first panel holder 820 and also at substantially the same height off the floor as the first panel holder 820. The second panel holder 830 is also completely removable from the handler 570 for filling with untrimmed panels or for emptying trimmed panels therefrom. A third panel holder 850 is also provided as a special panel storage location. The third panel holder 850 is supported directly below the loading and unloading position of the panel fixture 510 by cantilevered support elements 811 of the frame 810.

The first panel holder 820 is accessible to the operator via a first door 825 which is disposed at a front side of the handler assembly 570. The second panel holder 830 is accessible to the operator via a second door 835, which is also disposed at the front side of the handler assembly 570. Each of the doors 825 835 is supported by the frame 810 and hinged to open upwardly and to be held in an open position during the loading or unloading of panel holder 820 and 830 from the panel handler 570. Accordingly, an operator can readily access either or both panel holder 820 830 from the front of the handler assembly 570 without disturbing the operation of the trimming system which may be in the process of trimming a panel. As will be detailed below, either of the panel holders 820 and 830 may be used as a supply panel holder filled with untrimmed panels for delivery to the trimming system or and a receiving panel holder for receiving trimmed panels after they have been trimmed by the trimming system.

A preferred embodiment of a panel-moving device 835 is shown in FIG. 8b. The panel-moving device 835 is provided to attach to a single panel 730 and move the panel from a first position to any one of a plurality of other positions. The panel-moving device is also configured to attach to a single slip-sheet 720 and move the slip-sheet from a first position to any one of a plurality of other positions. As detailed in FIG. 8b, the panel handler includes a rail 840, which is supported by the frame 810 along a longitudinal axis of the panel handler 570 such that the rail 840 runs above each of the first, second and third panel holders 820 830 850 and the panel fixture 510 when the panel fixture is positioned in the loading and unloading position. The rail 840 movably supports a gantry 845, by a rolling or sliding contact, for movement substantially along the entire length of the rail 840. The gantry includes a servo controlled motor, position feedback device and servo driver. A pick-up head 870 extends downwardly from the gantry 845 supported by a vertically movable panel-lifting arm 860 that is movable along the Z-axis with respect to the gantry 845. The panel lifting arm 860 also includes a servo controlled motor, position feedback device and servo driver for controlling the position of the panel-lifting arm 860 for lifting or lowering a panel attached to the pick-up head 870. Using the lifter 860 and the gantry 845, the pick-up head 870 is movable longitudinally and vertically along the rail 840, as indicated by the two-headed arrows.

A lower surface 880 of the pick-up head 870 includes apertures that are connected to a vacuum system, (not shown) for drawing air through the apertures. The negative pressure developed at the pick-up head lower surface 880 by the vacuum system provides the necessary force to pick up a slip-sheet and a panel as required. The vacuum system further includes a manifold for directing vacuum pressure to each of the aperture in the lower surface 880 and may also include controllably flow valves for adjusting the vacuum pressure to different levels. Also included is a vacuum system controller, for controlling the attachments and removal of a panel or slip-sheet to the pick-up head 870 and for adjusting the level of vacuum pressure at the pick-up head apertures. The panel-moving device 835 also includes a panel moving device controller 837. The panel moving device controller 837 may include all of the controls for moving a panel or slip-sheet from a first position to any other position and includes a communication link 838 to the system controller 550.

According to the invention, the gantry 845 is capable of motion along the rail 840 to position the panel lifter and attached pick-up head 870 precisely over the second holder 830, the first holder 820 and the panel fixture 510, when the panel fixture is in the loading and unloading position. Moreover, the panel-lifter 860 is configure to be movable for placing the panel pick-up head bottom surface 880 into contact with any panel stacked in one of the panel holders 820, 830 and 850. Of course the panel fixture 510 must be moved out of the loading and unloading position before the panel pick-up head 870 can be lowered to the special panel holder 850.

The tops surfaces of the panels and/or slip-sheets in the holders 820 and 830 and the special panel holder 850 may be at different vertical positions along the travel of the lifter. The lifter is constructed and controlled such that panels and/or slip-sheets may be picked up from and placed to any particular surface location, along the vertical travel of the lifter, that may be present during operation.

Referring again to FIG. 8b, it should be noted that in this side by side configuration of the holders 820 and 830, the pick-up head 870 can be a very simple assembly since it need only move longitudinally along the rail to be positioned directly over the holders 820 and 830, the panel fixture 510, and the special panel holder 850.

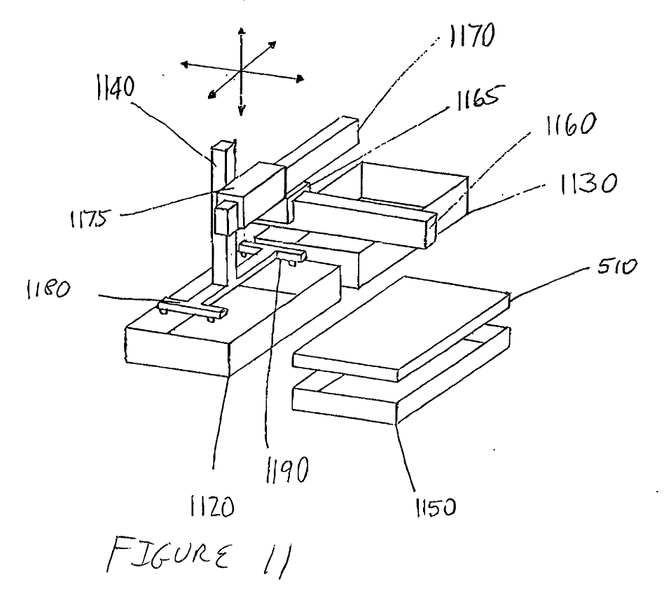

The preferred configuration of the pick-up head 870 and a panel holder 820, 830, 840 is depicted in FIG. 9. The panel holder contains one or more panels 950 and/or slip-sheets 960 in a horizontal stacked configuration. Each panel may be separated by a slip-sheet, and a slip-sheet may be present at either or both of the top and bottom of the stack. FIG. 9 also shows the apertures on the pick-up head through which the vacuum required to pick up a panel or slip-sheet is applied. The lifter is capable of downward vertical travel to the bottom of the holder and upward travel to a position above the height of the panel holder so that the panel held in place by the pick-up head is clear of the holder and other obstructions for movement by the gantry 915 along the rail 910.

The holders 820 and 830 and the special panel holder 850 are constructed to hold zero or more panels and/or slip-sheets. Preferably, the holders are capable of storing many panels, with or without interleaved slip-sheets, sufficient for prolonged operation of the automated trimmer system 500 without the need for operator loading or unloading of panels. This prolonged operation may be of the order of a standard work shift (7-12 hours), or longer. The number of panels, and slip-sheets if present, that are preferably stored in the holders is dependent upon the thickness and/or weight of the panels and/or slip-sheets, the time required to fully trim each panel, and other factors particular to the job.

In operation, an operator, from the front of the trimming system 500, opens the door 825 and removes the first panel holder 820. The operator inserts a plurality of untrimmed panels into the holder 820. The holder 820, with the untrimmed panels inserted therein is then reinstalled in the handler assembly 570 and the door 825 is closed.

If a slip-sheet is present at the top surface of the holder 820 contents, under the control of the controller 550 the panel handler pick-up head 930 moves along the panel handler rail 840 to position the bottom surface 880 of the pick-up head 870 directly over the holder 820. The pick-up head 870 is lowered by the lifter 860 and a vacuum pressure applied through the apertures on the lower side 880 forces the slip-sheet against the pick-up head lower surface 880. The pick-up head 870 is then raised by the lifter 860 and moved along the rail 840 to position the bottom surface 880 of the pick-up head 870 directly over the holder 830. The pick-up head is lowered and the vacuum is shut off at the pick-up head lower surface 880 to release the slip-sheet. The pick-up head is then raised, leaving the slip-sheet in the holder 830.

The panel handler pick-up head 870 is now moved along the rail 840 to again position the bottom surface 880 of the pick-up head 870 directly over the holder 820. The pick-up head is lowered and a vacuum forces the top untrimmed panel against the pick-up head lower surface 880. The pick-up head 870 is then raised and moved along the rail 840 to position the bottom surface 880 of the pick-up head 870 directly over the panel fixture 510. The pick-up head is lowered and the vacuum is shut off at the pick-up head lower surface 880 to release the untrimmed panel. The pick-up head is then raised, leaving the untrimmed panel on the panel fixture 510. The pick-up head may now be moved to a parked position, out of the way of trimming operation, which could be located over one of the holders 820 and 830 along the rail 840. The untrimmed panel is clamped on the panel fixture 510 using vacuum or other well known techniques, and the trimming sequence described above proceeds.

During operation of the trim sequence, the next slip-sheet present at the top surface of the contents of untrimmed panel holder 820 may be moved to the trimmed panel holder 830. Under the control of the controller 550 the panel handler pick-up head 870 moves along the panel handler rail 840 to position the bottom surface 880 of the pick-up head 870 directly over the holder 820. The pick-up head is lowered by the lifter and a vacuum forces the slip-sheet against the pick-up head lower surface 880. The pick-up head 870 is then raised by the lifter 860 and moved along the rail 840 to position the bottom surface 880 of the pick-up head 870 directly over the holder 830. The pick-up head is lowered and the vacuum is shut off at the pick-up head lower surface 880 to release the slip-sheet. The pick-up head is then raised, leaving the slip-sheet in the second panel holder 830, and the panel handler may be moved to a parked position.

After trimming is completed for the entire panel, the panel fixture 510 is moved to the loading and unloading position and the panel handler pick-up head 870 is moved along the rail 840 from the parked position to again position the bottom surface 880 of the pick-up head 870 directly over the panel fixture 510. The pick-up head is lowered and a vacuum forces the top of the trimmed panel against the pick-up head lower surface 880. The pick-up head 870 is then raised and moved along the rail 840 to position the bottom surface 880 of the pick-up head 870 directly over the second panel holder 830. The pick-up head is lowered and the vacuum is shut-off at the pick-up head lower surface 880 to release the trimmed panel at the holder 830. The pick-up head is then raised, leaving the trimmed panel in the holder 830. The trimmed panel is stored in the holder 830 until removed by the operator.

Under the control of the controllers 550 and 837, the panel handling and trimming sequence described above is repeated until all of the panels located in the untrimmed panel holder 820 have been trimmed and placed in the trimmed panel holder 830. Alternatively, the panel handling and trimming sequence described above is repeated until a desired number of panels located in the untrimmed panel holder 820 have been trimmed and placed in the trimmed panel holder 830. The desired number of panels may number from one to the total number of panels located in the untrimmed panel holder 820. Trimming of less than the total number of panels located in the untrimmed panel holder 820 may be desired for batch checking or other fabrication process related reasons. The desired number of panels to be trimmed by the automated trimming system may be set by the operator or stored job parameter and is termed the batch.

During processing of the panels described above, it may be desirable for a panel and/or slip-sheet to be moved from either of the first or second panel holders 820, 830 or the panel fixture 510 to the special panel holder 850. As described earlier, the reasons for this special consideration include, but are not limited to, an abnormal condition encountered during trimming, a defect in the panel, a defect with the trimming or measurement results, and separation of the panel for inspection. The sequence of operations involving the components of the handler assembly are similar to those described above for moving panels and slip-sheets between panel holders and the panel fixture, except that the destination of the panel or slip-sheet is now the special panel holder 850. With reference again to FIG. 8b, it may be seen that the panel fixture 510 in its load/unload location is blocking access of the pick-up head to the special panel holder. As described previously, the panel fixture 510 is mounted to an XY stage that is capable of moving the panel fixture to the particular circuit trimming location. Thus an integral step in the sequence of moving a panel and/or slip-sheet from either of the trimmed or untrimmed panel holders or the panel fixture 510 to the special panel holder 850 is to move the panel fixture 510, using the X-Y stage, clear from over the special panel holder when access to the special panel holder is required.

Once the holder 830 is full, or the job is completed, or the batch has been trimmed, the operator, from the front side of the trimming system, opens the door 835 and removes the second panel holder 830, which is filled with trimmed panels. The operator may replace the second panel holder 830 with another empty panel holder in the handler assembly 570 and the door 835 is closed. In this case, the first panel holder 820 must be refilled with another batch of panels to be trimmed. The first panel holder 820 may be removed from the system to be filled and replaced, replaced by a full holder or filled in place or partially removed from the handler assembly 570. Alternatively, the operator may remove the second panel holder 830, which is filled with trimmed panels, remove the trimmed panels and then refill the second panel holder 830 with untrimmed panels and reinstall the second panel holder 830 into the handler assembly 570 and the door 835 is closed. In the case where the first panel holder 820 is empty and the second panel holder 830 is filled with untrimmed panels. The operator may then initiate a trimming job which takes untrimmed panels from the second panel holder 830 and placed trimmed panels in the first panel handler 820. Proper operation of the handler assembly in the trimming sequence is now possible simply by switching the respective definitions for the locations of the two holders 820 and 830 in the handler assembly at the controller. This method provides the operator a means for quick reloading of the automated trimming system by exchanging only a single holder on a reload operation.

Although not shown in FIG. 8, beneficially the remainder of the trimming system including panel fixture, X-Y stage, laser, probe assembly and controller is also enclosed by an enclosure containing a door which can be opened from the front of the trim system by the operator to insert or remove a single panel at the panel fixture 510. Hence, the embodiment of FIG. 8 provides a front loading trim system into which either a single panel can be manually inserted directly onto the panel fixture by the operator for trimming or into which multiple panels can be inserted into a holder by the operator and automatically loaded on and removed from the panel fixture 510 by a panel handler assembly 570 under the control of the system controller 550.

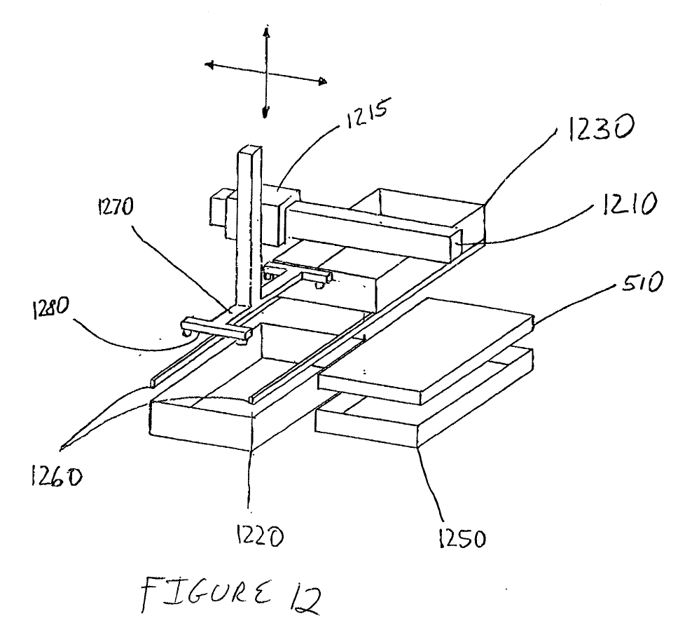

FIG. 10 depicts a second embodiment of the handler assembly 570. The FIG. 10 handler assembly is similar to that of FIG. 8, except that the FIG. 10 handler serves to handle the panels and/or slip-sheets of two trimming subsystems simultaneously. According to the second embodiment, a panel handler includes first and second panel holders 1020 and 1030. In the second embodiment, two and two panel fixtures 1040a and 1040b belonging to two different laser trimming subsystems each substantially similar to the system shown in FIG. 5. The assembly 570 includes a support frame (not shown) similar to frame 810 of FIG. 8. The frame supports a first panel holder 1020 for receiving trimmed panels therein from each of the two trimming subsystems or for distributing untrimmed panels to each of the trimming subsystems. Similarly, the frame 810 supports a second panel holder 1030 for receiving trimmed panels therein from each of the two trimming subsystems or for distributing untrimmed panels to each of the trimming subsystems. Each of the first and second panel holders 1020 1030 are easily accessible by an operator for removal or replacement from front side of the handler assembly 570. Also present are special panel storage holders 1050a and 1050b positioned under each of the panel fixtures 1040a and 1040b. As described above, doors like the doors 825 835 shown in FIG. 8a may be provided mounted to the frame 810.

A panel handler is provided to load untrimmed panels from the holder 1020 onto either or both of the panel fixtures 1040a and 1040b and to move trimmed panels from the panel fixtures 1040a and 1040b to the holder 1030. The panel handler is also used to move slip-sheets from the untrimmed panel holder 1020 to the trimmed panel holder 1030 if the untrimmed panels are separated by slip-sheets. As detailed in FIG. 10, the panel handler includes a rail 1010 that is configured to access to each of the panel loading or unloading positions. In this case a single panel handler controller 873 may be in communication with two system controllers 550 for receiving loading and unload instruction from both of the trimming subsystems associated therewith.

Referring again to FIG. 10, it should be noted that in this side by side configuration of the holders 1020 and 1030, the pick-up head 1070 can be a very simple assembly since it need only move longitudinally along the rail to be positioned directly over the holders 1020 and 1030, the panel fixtures 1040a and 1040b, and the special panel holders 1050a and 1050b. It should also be noted that in this dual trimmer side-by-side configuration, the cost of the panel handler assembly is reduced compared to providing the similar function separately for two automated trimming systems.

As in the system described above, the holders 1020 and 1030 and the special panel holders 1050a and 1050b are constructed to hold zero or more panels and/or slip-sheets. Preferably, the holders are capable of storing many panels, with or without interleaved slip-sheets, sufficient for prolonged operation of the automated trimmer system without the need for operator loading or unloading of panels. This prolonged operation may be of the order of a standard work shift (7-12 hours), or longer. The number of panels, and slip-sheets if present, that are preferably stored in the holders is dependent upon the thickness and/or weight of the panels and/or slip-sheets, the time required to fully trim each panel, and other factors particular to the job.

In operation, an operator, from the front of the trimming system, opens the door (not shown) and removes the holder 1020. The operator inserts the untrimmed panels into the holder 1020. The holder 1020, with the untrimmed panels inserted, is then reinstalled in the handler assembly 570 and the door is closed.

If a slip-sheet is present at the top surface of the holder 1020 contents, under the control of the controller 550 the panel handler pick-up head 1070 moves along the panel handler rail 1010 to position the bottom surface 1080 of the pick-up head 1070 directly over the holder 1020. The pick-up head is lowered by the lifter and a vacuum forces the slip-sheet against the pick-up head lower surface 1080. The pick-up head 1070 is then raised by the lifter 1060 and moved along the rail 1010 to position the bottom surface 1080 of the pick-up head 1070 directly over the holder 1030. The pick-up head is lowered and the vacuum is shut off at the pick-up head lower surface 1080 to release the slip-sheet. The pick-up head is then raised, leaving the slip-sheet in the holder 1030.

The panel handler pick-up head 1070 is now moved along the rail 1010 to again position the bottom surface 1080 of the pick-up head 1070 directly over the holder 1020. The pick-up head is lowered and a vacuum forces the top untrimmed panel against the pick-up head lower surface 1080. The pick-up head 1070 is then raised and moved along the rail 1010 to position the bottom surface 1080 of the pick-up head 1070 directly over the panel fixture 1040a. The pick-up head is lowered and the vacuum is shut off at the pick-up head lower surface 1080 to release the untrimmed panel. The pick-up head is then raised, leaving the untrimmed panel on the panel fixture 1040a. The pick-up head may now be moved to a parked position, out of the way of trimming operation, which could be located over one of the holders 1020 and 1030 along the rail 1010. The untrimmed panel is clamped on the panel fixture 1040a using vacuum or other well known techniques, and the trimming sequence described above proceeds at the trimming subsystem associated with panel fixture 1040a.

If a slip-sheet is now present at the top surface of the holder 1020 contents, under the control of the controller 550 the panel handler transfers the slip-sheet from holder 1020 to holder 1030 in the same sequence as described above.

The panel handler pick-up head 1070 is now moved along the rail 1010 to again position the bottom surface 1080 of the pick-up head 1070 directly over the holder 1020. The pick-up head is lowered and a vacuum forces the top untrimmed panel against the pick-up head lower surface 1080. The pick-up head 1080 is then raised and moved along the rail 1010 to position the bottom surface 1080 of the pick-up head 1070 directly over the panel fixture 1040b. The pick-up head is lowered and the vacuum is shut off at the pick-up head lower surface 1080 to release the untrimmed panel. The pick-up head is then raised, leaving the untrimmed panel on the panel fixture 1040b. The pick-up head may now be moved to a parked position, out of the way of trimming operation, which could be located over one of the holders 1020 and 1030 along the rail 1010. The untrimmed panel is clamped on the panel fixture 1040b using vacuum or other well known techniques, and the trimming sequence described above proceeds at the trimming subsystem associated with panel fixture 1040b.

The transfer of panels to both trimming subsystems associated with panel fixtures 1040a and 1040b is thus accomplished, allowing both trimming subsystems to trim in parallel. A panel handling assembly depicted in FIG. 10, similar to the preferred embodiment depicted in FIG. 8, is thus able to serve two trimming subsystems with a minor change to the travel of the gantry 1015 on the rail 1010 to reach two panel fixtures 1040a and 1040b. The operation, loading and unloading of the of the panel handler embodiment shown in FIG. 10 is substantially the same as described above except that any panel or slip-sheet may be transported from a first location to any one of the panel fixtures 1040a, 1040b, the first and second panel holders 1020 and 1030 and the special panel holders 1050a and 1050b.

Although not shown in FIG. 10, beneficially the remainder of each of the trimming subsystems, including panel fixture, X-Y stage, laser, probe assembly and controller, are also enclosed by enclosures containing doors which can be opened from the front of the trim system by the operator to insert or remove a single panel at the panel fixture 1040a or 1040b. Hence, the embodiment of FIG. 10 provides a front loading trim system into which either a single panel can be inserted directly onto either of the two trim subsystem panel fixtures by the operator for trimming or into which multiple panels can be inserted into a holder by the operator and automatically loaded on and removed from the two panel fixtures by a panel handler under the control of the controller.

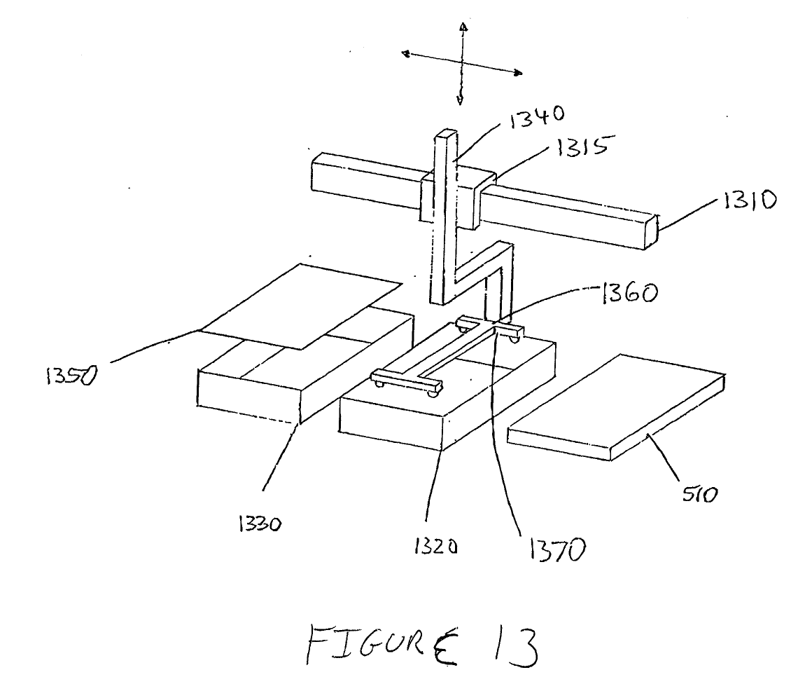

FIG. 11 depicts a third embodiment of the handler assembly 570. The FIG. 11 handler assembly is similar to that of FIG. 8, except that instead of being disposed side by side, the untrimmed panel holder and the trimmed panel holder are disposed in a front to rear configuration. The panel fixture 510 is shown adjacent to the panel handler for receiving panels therefrom.

In FIG. 11, the assembly 570 includes a support frame (not shown) similar to frame 810 of FIG. 8. The frame supports first and second panel holder 1120 and 1030 which can be easily removed from and reinstalled into the handler assembly 570 to insert or remove panels therefrom. Also present is a special panel storage location, which also preferably includes a special panel holder 1150 in which special panels can be stored as required during operation of the automated trimming system.

The first panel holder 1120 is accessible to the operator from a front side of the system 500 via a door (not shown), similar to the door 825 of FIG. 8, which is disposed at the front of the handler assembly 570. The trimmed panel holder 1130 is accessible to the operator via a door (not shown), which may be similar to the door 835 of FIG. 8 and disposed at either a left side or a rear side of the handler assembly 570. Accordingly, the operator can load untrimmed panels through the front side door a remove trimmed panels from the one of the left side and the rear of the handler assembly.

A two axis panel handler 1140 is provided to load untrimmed panels from the holder 820 onto the panel fixture 510 and to move trimmed panels from the panel fixture 510 to the holder 830. The panel handler is also used to move slip-sheets from the untrimmed panel holder 820 to the trimmed panel holder 830 if the untrimmed panels are separated by slip-sheets.

As shown in FIG. 11, the panel handler includes a first support rail 1160 with gantry 1165 and a second orthogonal support rail 1170 with gantry 1175, a lifter 1140, and a pick-up head 1180. The pick-up head is mounted on the lifter which in turn is mounted on the second gantry 1175 which moves along the second rail 1170. The second rail is mounted to the first gantry 1165 which in turn moves along the first rail 1160. Using the lifter 920 and the gantry 1165, the pick-up head 1180 is movable left, right, and vertically along the rail 1160 such that it may be positioned over the untrimmed panel holder 1120, the special panel holder 1150, or the panel fixture 510. Using the lifter 1140 and the gantry 1175, the pick-up head 1180 is movable frontwards, backwards, and vertically along the rail 1170 such that it may be positioned over the untrimmed panel holder 1120 or the trimmed panel holder 1130. A lower surface 1190 of the pick-up head 1180 includes apertures that are connected to a vacuum pump (not shown). The negative pressure developed at the pick-up head lower surface 1190 by the vacuum pump provides the necessary force to pick up the slip-sheets and panels as required. To release the slip-sheet or panel from the pick-up head 1180, the vacuum at the pick-up head lower surface is turned off either by closing a valve upstream of the apertures or by turning off the pump.

The holder 1120, the panel fixture 510, and the special panel holder 1150 are located along a straight line and parallel to the rail 1160. The holder 1120 and the trimmed panel holder 1130 are located along a straight line and parallel to the rail 1170. The gantry 1165 is capable of motion along the rail 1160 to position the lifter and pick-up head over the holder 1120 and the panel fixture 510. The gantry 1165 is also capable of controlled motion to position and stop the lifter and pick-up head over intermediate locations along the rail for access to the special panel holder 1150. The gantry 1175 is capable of motion along the rail 1170 to position the lifter and pick-up head over the holder 1120 and the holder 1130.

The lifter is capable of vertical motion sufficient to pick up and place panels and slip-sheets at each of the panel holding and fixing locations. The tops surfaces of the panels and/or slip-sheets in the holders 1120 and 1130 and the special panel holder 1150 may be at different vertical positions along the travel of the lifter 1140. The lifter is constructed and controlled such that panels and/or slip-sheets may be picked up from and placed to any particular surface location, along the vertical travel of the lifter, that may be present during operation.

Referring again to FIG. 11, it should be noted that in this front and back configuration of the holders 1120 and 1130, the pick-up head 1180 requires additional movement frontwards and backwards to access the trimmed panel holder 1130, beyond the longitudinal motion required for positioning over holder 1120, the panel fixture 510, and the special panel holder 1150. It should also be noted that in this front and back configuration of the holders 1120 and 1130, the width of the handler assembly is reduced from that of the preferred embodiment depicted in FIG. 8, but at the expense of additional complexity.

In operation, an operator, from the front of the trimming system, opens the door and removes the holder 1120. The operator inserts the untrimmed panels into the holder 1120. The holder 1120, with the untrimmed panels inserted, is then reinstalled in the handler assembly 570 and the door is closed.

If a slip-sheet is present at the top surface of the holder 1120 contents, under the control of the controller 550 the panel handler pick-up head 1180 moves along the panel handler rail 1170 to position the bottom surface 1190 of the pick-up head 1180 directly over the holder 1120. The pick-up head is lowered by the lifter and a vacuum forces the slip-sheet against the pick-up head lower surface 1190. The pick-up head 1180 is then raised by the lifter 140 and moved along the rail 1170 to position the bottom surface 1190 of the pick-up head 1180 directly over the holder 1130. The pick-up head is lowered and the vacuum is shut off at the pick-up head lower surface 1190 to release the slip-sheet. The pick-up head is then raised, leaving the slip-sheet in the holder 1130.

The panel handler pick-up head 1180 is now moved along the rail 1170 to again position the bottom surface 1190 of the pick-up head 1180 directly over the holder 1120. The pick-up head is lowered and a vacuum forces the top untrimmed panel against the pick-up head lower surface 1190. The pick-up head 1180 is then raised and moved along the rail 1160 to position the bottom surface 1190 of the pick-up head 1180 directly over the panel fixture 510. The pick-up head is lowered and the vacuum is shut off at the pick-up head lower surface 1190 to release the untrimmed panel. The pick-up head is then raised, leaving the untrimmed panel on the panel fixture 510. The pick-up head may now be moved to a parked position, out of the way of trimming operation, which could be located over one of the holders 1120 and 1130 along the rails 1160 and 1170. The untrimmed panel is clamped on the panel fixture 510 using vacuum or other well known techniques, and the trimming sequence proceeds.

During operation of the trim sequence, the next slip-sheet present at the top surface of the contents of untrimmed panel holder 1120 may be moved to the trimmed panel holder 1130. Under the control of the controller 550 the panel handler pick-up head 1180 moves along the rail 1170 to position the bottom surface 1190 of the pick-up head 1180 directly over the holder 1120. The pick-up head is lowered by the lifter and a vacuum forces the slip-sheet against the pick-up head lower surface 1190. The pick-up head 1180 is then raised by the lifter 1140 and moved along the rail 1170 to position the bottom surface 1190 of the pick-up head 1180 directly over the holder 1130. The pick-up head is lowered and the vacuum is shut off at the pick-up head lower surface 1190 to release the slip-sheet. Here again, the pick-up head is then raised, leaving the slip-sheet in the holder 1130, and the panel handler may be moved to a parked position.

After trimming is completed for the entire panel, the panel handler pick-up head 1180 is moved along the rail 1160 from the parked position to again position the bottom surface 1190 of the pick-up head 1180 directly over the panel fixture 510. The pick-up head is lowered and a vacuum forces the top of the trimmed panel against the pick-up head lower surface 1190. The pick-up head 1180 is then raised and moved along the rail 1160 and 1170 to position the bottom surface 1190 of the pick-up head 1180 directly over the holder 1130. The pick-up head is lowered and the vacuum is shut-off at the pick-up head lower surface 1190 to release the trimmed panel at the holder 1130. The pick-up head is then raised, leaving the trimmed panel in the holder 1130. The trimmed panel is stored in the holder 1130 until removed by the operator.

Here again, under the control of the controllers 837 and 550, the panel handling and trimming sequence described above is repeated until all of the panels located in the untrimmed panel holder 1120 have been trimmed and placed in the trimmed panel holder 1130. Alternatively, the panel handling and trimming sequence described above is repeated until a desired number of panels located in the untrimmed panel holder 1120 have been trimmed and placed in the trimmed panel holder 1130. The desired number of panels may number from one to the total number of panels located in the untrimmed panel holder 1120. Trimming of less than the total number of panels located in the untrimmed panel holder 1120 may be desired for batch checking or other fabrication process related reasons. The desired number of panels to be trimmed by the automated trimming system may be set by the operator or stored job parameter and is termed the batch. As in the systems above, a special panel holder 1150 is also provided.

Once the holder 1130 is full, or the job is completed, or the batch has been trimmed, the operator, from the front of the trimming system, opens the door (not shown) and removes the holder 1130. The operator replaces the holder 1130 with another empty trimmed panel holder in the handler assembly 570 and the door is closed. Alternatively, the operator removes the trimmed panels from the holder 1130 and then the empty holder 1130 is reinstalled in the handler assembly 570 and the door is closed.

In the case where the untrimmed panel holder 1120 is empty and the trimmed panel holder 1130 contains all of the panels in the system, it may be preferable that the operator, from the front of the trimming system, opens the door and removes the holder 1130. The operator then replaces the holder 1130 with an untrimmed panel holder, similar to holder 1120, containing one or more panels and slip-sheets, in the handler assembly 570 at the location previously occupied by holder 1130, and the door is closed. The handler assembly 570 now contains an untrimmed panel holder containing one or more panels and slip-sheets at the location previously occupied by the trimmed panel holder, and an empty trimmed panel holder at the location previously occupied by the untrimmed panel holder. Proper operation of the handler assembly in the trimming sequence is now possible simply by switching the respective definitions for the locations of the two holders 1120 and 1130 in the handler assembly at the controller. This method provides the operator a means for quick reloading of the automated trimming system by exchanging a single holder.

FIG. 12 depicts a fourth embodiment of the handler assembly 570 of FIG. 5. The FIG. 12 handler assembly is similar to that of FIG. 11, with the untrimmed panel holder and the trimmed panel holder disposed in a front to rear configuration. However, in the FIG. 12 embodiment, the trimmed panel holder is disposed on a different plane from the untrimmed panel holder and is moveable from a parked position towards the rear of the trimming system to a load/unload position above the untrimmed panel holder.

In FIG. 12, the assembly 570 includes a support frame (not shown) similar to frame 810 of FIG. 8. The frame supports an untrimmed panel storage location, which preferably includes a removable untrimmed panel holder 1220 which can be easily removed from the handler assembly 570 to insert untrimmed panels for storage and then easily reinstalled in the handler assembly 570 when the inserted panels are required for a job. The frame also supports a trimmed panel storage location, which also preferably includes a removable trimmed panel holder 1230 which can be easily removed from the handler assembly 570 to remove trimmed panels from storage and easily reinstalled in the handler assembly 570 in an empty state so that additional trimmed panels can be stored at the handler assembly as required during processing. Also present is a special panel storage location, which also preferably includes a special panel holder 1250 in which special panels can be stored as required during operation of the automated trimming system.

The untrimmed panel holder 1220 is accessible to the operator via a door (not shown), similar to the door of FIG. 8, which is disposed at the front of the handler assembly 570. The trimmed panel holder 1230 is accessible to the operator via the same door and by moving the holder 1230 to the front and over the top of the untrimmed panel holder 1220. Accordingly, the operator can access both the untrimmed panel holder to insert untrimmed panels and the trimmed panel holder to remove trimmed panels from the front of the handler assembly.

A panel handler is provided to load untrimmed panels from the holder 1220 onto the panel fixture 510 and to move trimmed panels from the panel fixture 510 to the holder 1230. The panel handler is also used to move slip-sheets from the untrimmed panel holder 1220 to the trimmed panel holder 1230 if the untrimmed panels are separated by slip-sheets. The trimmed panel holder 1230 is controlled by the controller to move to the front and to the rear such that the pick-up head 1270 may access the untrimmed panel holder 1220 when the holder 1230 is parked towards the rear of it's travel, and the pick-up head 1270 may access the trimmed panel holder 1230 when it is moved to the front and over top of the untrimmed panel holder 1220.

As shown in FIG. 12, the panel handler includes a rail 1210, a gantry 1215, a lifter 1240, and a pick-up head 1270. The pick-up head is mounted on the lifter which in turn is mounted on the gantry which in turn is mounted on the rail. Using the lifter 1240 and the gantry 1215, the pick-up head 1270 is movable longitudinally and vertically along the rail 1210, as indicated by the two-headed arrows. The panel handler also includes a slider 1260 which moves the trimmed panel holder 1230 to a parked position towards the rear of the handler assembly, and to the front and over top of the untrimmed panel holder 1220 as necessary during operation. The slider 1260 may be constructed such that the holder 1230 moves by sliding action, rolling action, lever action, or other means. A lower surface 1280 of the pick-up head 1270 includes apertures that are connected to a vacuum pump (not shown). The negative pressure developed at the pick-up head lower surface 1280 by the vacuum pump provides the necessary force to pick up the slip-sheets and panels as required. To release the slip-sheet or panel from the pick-up head 1270, the vacuum at the pick-up head lower surface is turned off either by closing a valve upstream of the apertures or by turning off the pump.

The holder 1220, the panel fixture 510, and the special panel holder 1250 are located along a straight line and parallel to the rail 910. When the trimmed panel holder 1230 is located at the front and over top of the untrimmed panel holder, the holder 1230 and holder 1220 are located directly on top of each other, along the axis of the lifter 1240. The gantry 1215 is capable of motion along the rail 1210 to position the lifter and pick-up head over the holder 1220, the holder 1230, and the panel fixture 510. The gantry 1215 is also capable of controlled motion to position and stop the lifter and pick-up head over intermediate locations along the rail for access to the special panel holder 1250

The lifter is capable of vertical motion sufficient to pick up and place panels and slip-sheets at each of the panel holding and fixing locations. The top surfaces of the panels and/or slip-sheets in the holders 1220 and 1230 and the special panel holder 1250 are at different vertical positions along the travel of the lifter. The lifter is constructed and controlled such that panels and/or slip-sheets may be picked up from and placed to any particular surface location, along the vertical travel of the lifter, that may be present during operation.

Referring again to FIG. 12, it should be noted that in this front and back configuration of the holders 1220 and 1230, the pick-up head 1270 is able to access the untrimmed panel holder 1220, the panel fixture 510, and the special panel holder 1250. Access of the pick-up head 1270 to the trimmed panel holder 1230 requires additional movement frontwards and backwards of the trimmed panel holder 1230, beyond the simple longitudinal motion required for positioning over holder 1220, the panel fixture 510, and the special panel holder 1250. It should also be noted that in this front and back configuration of the holders 1220 and 1230, access is possible to both holders 1220 and 1230 by an operator from the front of the automated trimming system. It should further be noted that in this front and back configuration of the holders 1220 and 1230, the width of the handler assembly is reduced from that of the preferred embodiment depicted in FIG. 8, but at the expense of additional complexity.

The preferred configuration of the pick-up head and a panel holder is depicted in FIG. 9. The panel holder contains one or more panels 950 and/or slip-sheets 960 in a horizontal stacked configuration. Each panel may be separated by a slip-sheet, and a slip-sheet may be present at either or both of the top and bottom of the stack. FIG. 9 also shows the apertures on the pick-up head through which the vacuum required to pick up a panel or slip-sheet is applied. The lifter is capable of downward vertical travel to the bottom of the holder and upward travel to a position above the height of the panel holder so that the panel held in place by the pick-up head is clear of the holder and other obstructions for movement by the gantry 915 along the rail 910.

The holders 1220 and 1230 and the special panel holder 1250 are constructed to hold zero or more panels and/or slip-sheets. Preferably, the holders are capable of storing many panels, with or without interleaved slip-sheets, sufficient for prolonged operation of the automated trimmer system without the need for operator loading or unloading of panels. This prolonged operation may be of the order of a standard work shift (7-12 hours), or longer. The number of panels, and slip-sheets if present, that are preferably stored in the holders is dependent upon the thickness and/or weight of the panels and/or slip-sheets, the time required to fully trim each panel, and other factors particular to the job.

In operation, an operator, from the front of the trimming system, opens the door (not shown) and removes the holder 1220. The operator inserts the untrimmed panels into the holder 1220. The holder 1220, with the untrimmed panels inserted, is then reinstalled in the handler assembly 570 and the door is closed. The trimmed panel holder 1230 is moved by the controller 550 to the parked position at the rear of the assembly.

If a slip-sheet is present at the top surface of the holder 1220 contents, under the control of the controller 550 the panel handler pick-up head 1270 moves along the panel handler rail 1210 to position the bottom surface 1280 of the pick-up head 1270 directly over the holder 1220. The pick-up head is lowered by the lifter and a vacuum forces the slip-sheet against the pick-up head lower surface 1280. The pick-up head 1270 is then raised by the lifter 1240. The trimmed panel holder 1230 is then moved along the slider 1260 to the front and over top of the untrimmed panel holder to position the holder 1230 directly under the bottom surface 1280 of the pick-up head 1270. The pick-up head is lowered and the vacuum is shut off at the pick-up head lower surface 1280 to release the slip-sheet. The pick-up head is then raised, leaving the slip-sheet in the holder 1230.

The trimmed panel holder 1230 is moved by the controller 550 to the parked position at the rear of the assembly, out of the way of the untrimmed panel holder 1220. The panel handler pick-up head 1270 is still positioned directly over the holder 1220. The pick-up head is lowered and a vacuum forces the top untrimmed panel against the pick-up head lower surface 1280. The pick-up head 1270 is then raised and moved along the rail 910 to position the bottom surface 1280 of the pick-up head 1270 directly over the panel fixture 510. The pick-up head is lowered and the vacuum is shut off at the pick-up head lower surface 1280 to release the untrimmed panel. The pick-up head is then raised, leaving the untrimmed panel on the panel fixture 510. The pick-up head may now be moved to a parked position, out of the way of trimming operation, which could be located over the holder 1220 along the rail 1210. The untrimmed panel is clamped on the panel fixture 510 using vacuum or other well known techniques, and the trimming sequence proceeds.

During operation of the trim sequence, the next slip-sheet present at the top surface of the contents of untrimmed panel holder 1220 may be moved to the trimmed panel holder 1230. Under the control of the controller 550 the panel handler pick-up head 1270 moves along the rail 910 to position the bottom surface 1280 of the pick-up head 1270 directly over the holder 1220 if it is not already at this position. The pick-up head is lowered by the lifter and a vacuum forces the slip-sheet against the pick-up head lower surface 1280 The trimmed panel holder 1230 is then moved along the slider 1260 to the front and over top of the untrimmed panel holder to position the holder 1230 directly under the bottom surface 1280 of the pick-up head 1270. The pick-up head is lowered and the vacuum is shut off at the pick-up head lower surface 1280 to release the slip-sheet. The pick-up head is then raised, leaving the slip-sheet in the holder 1230, and the trimmed panel holder 1230 is also now positioned to accept the trimmed panel after trimming is complete.

After trimming is completed for the entire panel, the panel handler pick-up head 1270 is moved along the rail 1210 from the parked position to again position the bottom surface 1280 of the pick-up head 1270 directly over the panel fixture 510. The pick-up head is lowered and a vacuum forces the top of the trimmed panel against the pick-up head lower surface 1280. The pick-up head 1270 is then raised and moved along the rail 1210 to position the bottom surface 1280 of the pick-up head 1270 directly over the holder 1230. The pick-up head is lowered and the vacuum is shut-off at the pick-up head lower surface 1270 to release the trimmed panel at the holder 1230. The pick-up head is then raised, leaving the trimmed panel in the holder 1230. The trimmed panel holder 1230 is then moved to the parked position at the rear of the assembly, out of the way of the untrimmed panel holder 1220. The trimmed panel is stored in the holder 1230 until removed by the operator.

Here again, under the control of the controller 550, the panel handling and trimming sequence described above is repeated until all of the panels located in the untrimmed panel holder 1220 have been trimmed and placed in the trimmed panel holder 1230. Alternatively, the panel handling and trimming sequence described above is repeated until a desired number of panels located in the untrimmed panel holder 1220 have been trimmed and placed in the trimmed panel holder 1230. The desired number of panels may number from one to the total number of panels located in the untrimmed panel holder 1220. Trimming of less than the total number of panels located in the untrimmed panel holder 1220 may be desired for batch checking or other fabrication process related reasons. The desired number of panels to be trimmed by the automated trimming system may be set by the operator or stored job parameter and is termed the batch.

During processing of the panels described above, it may be desirable for a panel and/or slip-sheet to be moved from either of the trimmed or untrimmed panel holders or the panel fixture 510 to the special panel holder 1250. As described earlier, the reasons for this special consideration include, but are not limited to, an abnormal condition encountered during trimming, a defect in the panel, a defect with the trimming or measurement results, and separation of the panel for inspection. The sequence of operations involving the components of the handler assembly are similar to those described above for moving panels and slip-sheets between panel holders and the panel fixture, except that the destination of the panel or slip-sheet is now the special panel holder 1250. With reference again to FIG. 12, it may be seen that the panel fixture 510 in its load/unload location is blocking access of the pick-up head to the special panel holder. As described previously, the panel fixture 510 is mounted to an XY stage that is capable of moving the panel fixture to the particular circuit trimming location. Thus an integral step in the sequence of moving a panel and/or slip-sheet from either of the trimmed or untrimmed panel holders or the panel fixture 510 to the special panel holder 1250 is to move the panel fixture 510, using the X-Y stage, clear from over the special panel holder when access to the special panel holder is required.

Once the holder 1230 is full, or the job is completed, or the batch has been trimmed, the operator, from the front of the trimming system, opens the door (not shown) and removes the holder 1230. The operator replaces the holder 1230 with another empty trimmed panel holder in the handler assembly 570 and the door is closed. Alternatively, the operator removes the trimmed panels from the holder 1230 and then the empty holder 1230 is reinstalled in the handler assembly 570 and the door is closed.

In the case where the untrimmed panel holder 1220 is empty and the trimmed panel holder 1230 contains all of the panels in the system, it may be preferable that the operator, from the front of the trimming system, opens the door and removes the holder 1230. The operator then replaces the holder 1230 with an untrimmed panel holder, similar to holder 1220, containing one or more panels and slip-sheets, in the handler assembly 570 at the location previously occupied by holder 1230, and the door is closed. The handler assembly 570 now contains an untrimmed panel holder containing one or more panels and slip-sheets at the location previously occupied by the trimmed panel holder, and an empty trimmed panel holder at the location previously occupied by the untrimmed panel holder. Proper operation of the handler assembly in the trimming sequence is now possible simply by switching the respective definitions for the locations of the two holders 1220 and 1230 in the handler assembly at the controller. This method provides the operator a means for quick reloading of the automated trimming system by exchanging a single holder.

Although not shown in FIG. 12, beneficially the remainder of the trimming system including panel fixture, X-Y stage, laser, probe assembly and controller is also enclosed by an enclosure containing a door which can be opened from the front of the trim system by the operator to insert or remove a single panel at the panel fixture 510. Hence, the embodiment of FIG. 12 provides a front loading trim system into which either a single panel can be inserted directly onto the panel fixture by the operator for trimming or into which multiple panels can be inserted into a holder 1220 by the operator and automatically loaded on and removed from the panel fixture by a panel handler under the control of the controller.

FIG. 13 depicts a fifth embodiment of the handler assembly 570 of FIG. 5. The FIG. 13 handler assembly is similar to that of FIG. 8, with the untrimmed panel holder 1320 and the trimmed panel holder 1330 disposed in a side by side configuration. However, in the FIG. 13 embodiment, the special panel holder 1350 is disposed over top of and on a different plane to the trimmed and untrimmed panel holders, and the panel fixture 510.

In FIG. 13, the assembly 570 includes a support frame (not shown) similar to frame 810 of FIG. 8. The frame supports an untrimmed panel storage location, which preferably includes a removable untrimmed panel holder 1320 which can be easily removed from the handler assembly 570 to insert untrimmed panels for storage and then easily reinstalled in the handler assembly 570 when the inserted panels are required for a job. The frame also supports a trimmed panel storage location, which also preferably includes a removable trimmed panel holder 1330 which can be easily removed from the handler assembly 570 to remove trimmed panels from storage and easily reinstalled in the handler assembly 570 in an empty state so that additional trimmed panels can be stored at the handler assembly as required during processing. Also present is a special panel storage location, which also preferably includes a special panel holder 1350 in which special panels can be stored as required during operation of the automated trimming system.

The untrimmed panel holder 1320 is accessible to the operator via a door (not shown), similar to the door 825 of FIG. 8, which is disposed at the front of the handler assembly 570. The trimmed panel holder 1330 is accessible to the operator via a door (not shown) similar to the door 825 of FIG. 8, which is also disposed at the front of the handler assembly 570. Accordingly, the operator can access both the untrimmed panel holder to insert untrimmed panels and the trimmed panel holder to remove trimmed panels from the front of the handler assembly 570. With reference to FIG. 13, it may be seen that the operator may also access the special panel holder 1350 from the front of the handler assembly through the door (not shown).

A panel handler is provided to load untrimmed panels from the holder 1320 onto the panel fixture 510 and to move trimmed panels from the panel fixture 510 to the holder 1330. The panel handler is also used to move slip-sheets from the untrimmed panel holder 1320 to the trimmed panel holder 1330 if the untrimmed panels are separated by slip-sheets. As detailed in FIG. 9, the panel handler includes a rail 1310, a gantry 1315, a lifter 1340, and a pick-up head 1360. The pick-up head is mounted on the lifter which in turn is mounted on the gantry which in turn is mounted on the rail. Using the lifter 1340 and the gantry 1315, the pick-up head 1360 is movable longitudinally and vertically along the rail 1310. A lower surface 1370 of the pick-up head 1360 includes apertures that are connected to a vacuum pump (not shown). The negative pressure developed at the pick-up head lower surface 13700 by the vacuum pump provides the necessary force to pick up the slip-sheets and panels as required. To release the slip-sheet or panel from the pick-up head 1360, the vacuum at the pick-up head lower surface is turned off either by closing a valve upstream of the apertures or by turning off the pump.

The holders 1320 and 1330, the panel fixture 510, and the special panel holder 1350 are located along a straight line and parallel to the rail 1310. The gantry 1315 is capable of motion along the rail 1310 to position the lifter and pick-up head over the holder 1330 and the panel fixture 510. The gantry 1315 is also capable of controlled motion to position and stop the lifter and pick-up head over intermediate locations along the rail for access to holder 1320 and the special panel holder 1350.

The lifter is capable of vertical motion sufficient to pick up and place panels and slip-sheets at each of the panel holding and fixing locations. The tops surfaces of the panels and/or slip-sheets in the holders 1320 and 1330 and the special panel holder 1350 are at different vertical positions along the travel of the lifter. The lifter is constructed and controlled such that panels and/or slip-sheets may be picked up from and placed to any particular surface location, along the vertical travel of the lifter, that may be present during operation. The embodiment depicted in FIG. 13 also requires that the lifter be controlled such that at least two positions along the vertical axis of the lifter be chosen during horizontal movement of the gantry 1315 to clear the special panel holder 1350. The lifter is also required to be positioned such that horizontal travel of the gantry 1315 and pick-up head 1360 does not interfere with the special panel holder 1350 when the lifter is in its lower traveling position. Access of the pick-up head 1360 to the holder 1330 and the special panel holder 1350 is accomplished by respectively raising above and lowering below the lifter and pick-up head 1360 relative to the special panel holder 1350 during horizontal motion.

Referring again to FIG. 13, it should be noted that in this side by side configuration of the holders 1320 and 1330, the pick-up head 1360 can be a simple assembly since it need only move longitudinally along the rail to be positioned directly over the holders 1320 and 1330, the panel fixture 510, and the special panel holder 1350. The lifter 1340 requires additional capability of at least two positions during horizontal travel to provide for access to and clearance from the special panel holder 1350.

The preferred configuration of the pick-up head and a panel holder is depicted in FIG. 9. The panel holder contains one or more panels 950 and/or slip-sheets 960 in a horizontal stacked configuration. Each panel may be separated by a slip-sheet, and a slip-sheet may be present at either or both of the top and bottom of the stack. FIG. 9 also shows the apertures on the pick-up head through which the vacuum required to pick up a panel or slip-sheet is applied. The lifter is capable of downward vertical travel to the bottom of the holder and upward travel to a position above the height of the panel holder so that the panel held in place by the pick-up head is clear of the holder and other obstructions for movement by the gantry 915 along the rail 910.

The holders 1320 and 1330 and the special panel holder 1350 are constructed to hold zero or more panels and/or slip-sheets. Preferably, the holders are capable of storing many panels, with or without interleaved slip-sheets, sufficient for prolonged operation of the automated trimmer system without the need for operator loading or unloading of panels. This prolonged operation may be of the order of a standard work shift (7-12 hours), or longer. The number of panels, and slip-sheets if present, that are preferably stored in the holders is dependent upon the thickness and/or weight of the panels and/or slip-sheets, the time required to fully trim each panel, and other factors particular to the job.

Operation of the panel handler assembly depicted in FIG. 13 is the same as that of the preferred embodiment described by FIG. 8, except that the lower of the lifter positions is chosen during routine panel and slip-sheet handling to and from the untrimmed panel holder 1320, the panel fixture 510, and the trimmed panel holder 1330. It is only in the case where a panel or slip-sheet is to be placed at the special panel holder 1350 that the upper lifter position is chosen during horizontal motion.

During processing of the panels described above, it may be desirable for a panel and/or slip-sheet to be moved from either of the trimmed or untrimmed panel holders or the panel fixture 510 to the special panel holder 1350. As described earlier, the reasons for this special consideration include, but are not limited to, an abnormal condition encountered during trimming, a defect in the panel, a defect with the trimming or measurement results, and separation of the panel for inspection. The sequence of operations involving the components of the handler assembly are similar to those described above for moving panels and slip-sheets between panel holders and the panel fixture, except that the destination of the panel or slip-sheet is now the special panel holder 850.

Specifically, if a panel or slip-sheet is to be moved from the trimmed panel holder 1330 to the special panel holder 1350, under the control of the controller 550 the panel handler pick-up head 1360 first moves to the lower lifter position and then moves along the panel handler rail 1310 to position the bottom surface 13700 of the pick-up head 1360 directly over the holder 1320. The pick-up head is lowered by the lifter and a vacuum forces the panel or slip-sheet against the pick-up head lower surface 1370. The pick-up head 1360 is then raised by the lifter 1340 and moved along the rail 1310 to position the pick-up head 1360 clear from under the special panel holder 1350. The pick up head then first raises to the upper lifter position and then moves along the panel handler rail 1310 to position the bottom surface 1370 of the pick-up head 1360 directly over the special panel holder 1350. The pick-up head is lowered and the vacuum is shut off at the pick-up head lower surface 1370 to release the panel or slip-sheet. The pick-up head is then raised, leaving the panel or slip-sheet in the special panel holder 1350.

Similar sequences to that described above are performed for movement of panels and/or slip-sheets from the untrimmed panel holder 1320 and the panel fixture 510 to the special panel holder 1350. The sequence of operations may be reversed to move the panel or slip-sheet from the special panel holder 1350 to the untrimmed panel holder 1320, the trimmed panel holder 1330, and the panel fixture 510.

Again, although not shown in FIG. 13, beneficially the remainder of the trimming system including panel fixture, X-Y stage, laser, probe assembly and controller is also enclosed by an enclosure containing a door which can be opened from the front of the trim system by the operator to insert or remove a single panel at the panel fixture 510. Hence, the embodiment of FIG. 8 provides a front loading trim system into which either a single panel can be inserted directly onto the panel fixture by the operator for trimming or into which multiple panels can be inserted into a holder by the operator and automatically loaded on and removed from the panel fixture by a panel handler under the control of the controller.

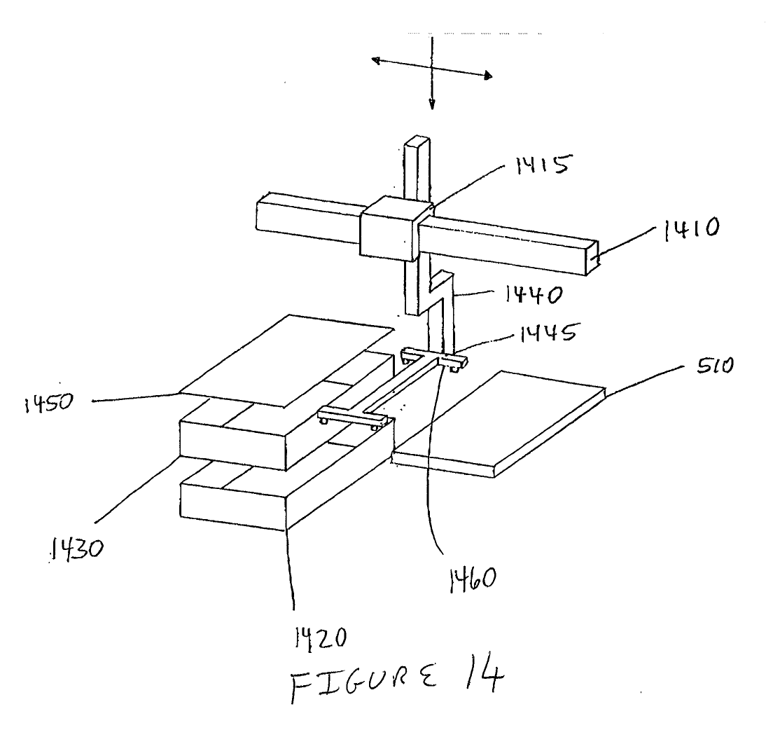

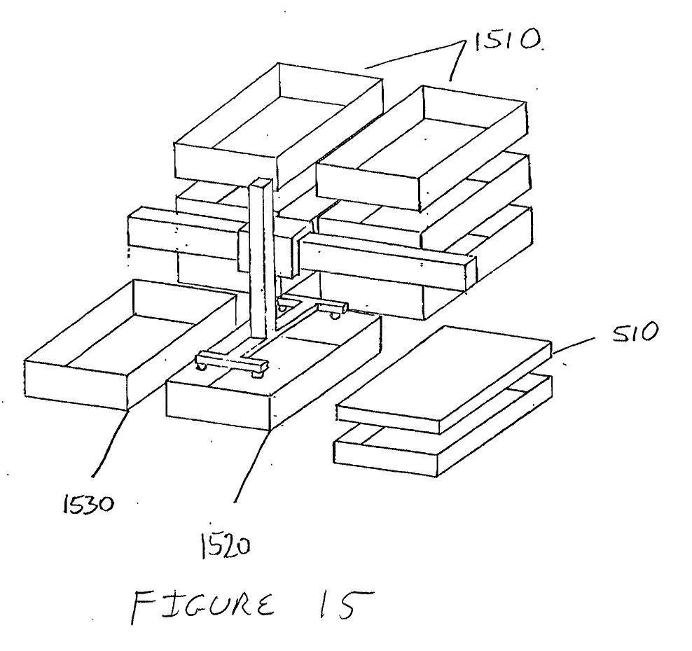

FIG. 14 depicts a sixth embodiment of the handler assembly 570 of FIG. 5. The FIG. 14 handler assembly is similar to that of FIG. 13, with the special panel holder 1450 and the trimmed panel holder 1430 disposed in a vertical configuration. However, in the FIG. 14 embodiment, the untrimmed panel holder 1420 is vertically disposed adjacent to the trimmed panel holder and the special panel holder.

In FIG. 14, the assembly 570 includes a support frame (not shown) similar to frame 810 of FIG. 8. The frame supports an untrimmed panel storage location, which preferably includes a removable untrimmed panel holder 1420 which can be easily removed from the handler assembly 570 to insert untrimmed panels for storage and then easily reinstalled in the handler assembly 570 when the inserted panels are required for a job. The frame also supports a trimmed panel storage location, which also preferably includes a removable trimmed panel holder 1430 which can be easily removed from the handler assembly 570 to remove trimmed panels from storage and easily reinstalled in the handler assembly 570 in an empty state so that additional trimmed panels can be stored at the handler assembly as required during processing. Also present is a special panel storage location, which also preferably includes a special panel holder 1450 in which special panels can be stored as required during operation of the automated trimming system.

The untrimmed panel holder 1420, is accessible to the operator via a door (not shown), similar to the door 825 of FIG. 8, which is disposed at the front of the handler assembly 570. The trimmed panel holder 1430 is accessible to the operator via the same or another door (not shown), also disposed at the front of the handler assembly 570. Accordingly, the operator can access both the untrimmed panel holder to insert untrimmed panels and the trimmed panel holder to remove trimmed panels from the front of the handler assembly 570. With reference to FIG. 14, it may be seen that the operator may also access the special panel holder 1450 from the front of the handler assembly through the same or similar door (not shown).

A panel handler is provided to load untrimmed panels from the holder 1420 onto the panel fixture 510 and to move trimmed panels from the panel fixture 510 to the holder 1430. The panel handler is also used to move slip-sheets from the untrimmed panel holder 1420 to the trimmed panel holder 1430 if the untrimmed panels are separated by slip-sheets. The panel handler includes a rail 1410, a gantry 1415, a lifter 1440, and a pick-up head 1445. The pick-up head is mounted on the lifter which in turn is mounted on the gantry which in turn is mounted on the rail. Using the lifter 1440 and the gantry 1415, the pick-up head 1445 is movable longitudinally and vertically along the rail 1410. A lower surface 1460 of the pick-up head 1445 includes apertures that are connected to a vacuum pump (not shown). The negative pressure developed at the pick-up head lower surface 940 by the vacuum pump provides the necessary force to pick up the slip-sheets and panels as required. To release the slip-sheet or panel from the pick-up head 1445, the vacuum at the pick-up head lower surface is turned off either by closing a valve upstream of the apertures or by turning off the pump.

The holders 1420 and 1430, the panel fixture 510, and the special panel holder 1450 are located along a straight vertical line and parallel to the lifter 1440 axis. The gantry 1415 is capable of motion along the rail 1410 to position the lifter and pick-up head over the three holders and the panel fixture 510. The gantry is also capable of stopping at an intermediate position along the rail 1410 that acts as a parked position for the pick-up head. This parked position is also the location where the pick-up head 1445 and lifter 1440 may be moved vertically without interference from the panel holders or the panel fixture 510, as is required during selection of the holder for panel removal and placement as described below.

The lifter is capable of vertical motion sufficient to pick up and place panels and slip-sheets at each of the panel holding and fixing locations. The tops surfaces of the panels and/or slip-sheets in the holders 1420 and 1430 and the special panel holder 1450 are at different vertical positions along the travel of the lifter. The lifter is constructed and controlled such that panels and/or slip-sheets may be picked up from and placed to any particular surface location, along the vertical travel of the lifter, that may be present during operation. The embodiment depicted in FIG. 14 also requires that the lifter be controlled such that at least three positions along the vertical axis of the lifter be chosen during horizontal movement of the gantry 1415 to clear the trimmed panel holder 1430 and the special panel holder 1450. The lifter is also required to be positioned such that horizontal travel of the gantry 1415 and pick-up head 1445 does not interfere with the trimmed panel holder 1430 and the special panel holder 1450 when the lifter is in its lower traveling positions. Access of the pick-up head 1445 to the holders 1420 and 1430 and the special panel holder 1450 is accomplished by raising above and lowering below the lifter and hence pick-up head 1445 relative to the three panel holders during horizontal motion.

Referring again to FIG. 14, it should be noted that in this vertical configuration of the holders 1420 and 1430, the pick-up head 1445 can be a simple assembly since it need only move longitudinally along the rail to be positioned directly over the holders 1420 and 1430, the panel fixture 510, and the special panel holder 1450. The lifter 1440 requires additional capability of at least three positions during horizontal travel to provide for access to and clearance from the trimmed panel holder 1430 and the special panel holder 1450. It should also be noted that in this over and above configuration of the holders 1420 and 1430, the width of the handler assembly is reduced from that of the preferred embodiment depicted in FIG. 8, but at the expense of additional complexity.

The preferred configuration of the pick-up head and a panel holder is depicted in FIG. 9. The panel holder contains one or more panels 950 and/or slip-sheets 960 in a horizontal stacked configuration. Each panel may be separated by a slip-sheet, and a slip-sheet may be present at either or both of the top and bottom of the stack. FIG. 9 also shows the apertures on the pick-up head through which the vacuum required to pick up a panel or slip-sheet is applied. The lifter is capable of downward vertical travel to the bottom of the holder and upward travel to a position above the height of the panel holder so that the panel held in place by the pick-up head is clear of the holder and other obstructions for movement by the gantry 915 along the rail 910.

The holders 1420 and 1430 and the special panel holder 1450 are constructed to hold zero or more panels and/or slip-sheets. Preferably, the holders are capable of storing many panels, with or without interleaved slip-sheets, sufficient for prolonged operation of the automated trimmer system without the need for operator loading or unloading of panels. This prolonged operation may be of the order of a standard work shift (7-12 hours), or longer. The number of panels, and slip-sheets if present, that are preferably stored in the holders is dependent upon the thickness and/or weight of the panels and/or slip-sheets, the time required to fully trim each panel, and other factors particular to the job.

Operation of the panel handler assembly depicted in FIG. 14 is similar to that of the embodiment described by FIG. 13, except that the lifter position is chosen during panel and slip-sheet handling to and from the untrimmed panel holder 1420, the panel fixture 510, and the trimmed panel holder 1430 to provide access to and clearance from the respective panel holders.

Specifically, if a panel or slip-sheet is to be moved from the untrimmed panel holder 1420 to the panel fixture 510, under the control of the controller 550 the panel handler pick-up head 1445 first moves along the rail 1410 to the parked position. The pick-up head and lifter then first move to the lowest lifter position and then move along the panel handler rail 1410 to position the bottom surface 1460 of the pick-up head 1445 directly over the holder 1420. The pick-up head is lowered by the lifter and a vacuum forces the panel or slip-sheet against the pick-up head lower surface 1460. The pick-up head 1445 is then raised by the lifter 1440 and moved along the rail 1410 to position the pick-up head 1445 at the parked position. The pick up head then first raises to an upper lifter position and then moves further along the panel handler rail 1410 to position the bottom surface 1460 of the pick-up head 1445 directly over the panel fixture 510. The pick-up head is lowered and the vacuum is shut off at the pick-up head lower surface 1460 to release the panel or slip-sheet. The pick-up head is then raised, leaving the panel or slip-sheet in the panel fixture 510.

Similar sequences but in reverse order are used to transfer panels and/or slip-sheets from the panel fixture 510 to the trimmed panel holder 1430.

During processing of the panels described above, it may be desirable for a panel and/or slip-sheet to be moved from either of the trimmed or untrimmed panel holders or the panel fixture 510 to the special panel holder 1450. As described earlier, the reasons for this special consideration include, but are not limited to, an abnormal condition encountered during trimming, a defect in the panel, a defect with the trimming or measurement results, and separation of the panel for inspection. The sequence of operations involving the components of the handler assembly are similar to those described above for moving panels and slip-sheets between panel holders and the panel fixture, except that the destination of the panel or slip-sheet is now the special panel holder 1450.

Similar sequences to that described above are performed for movement of panels and/or slip-sheets from the untrimmed panel holder 1420 and the panel fixture 510 to the special panel holder 1450. The sequence of operations may be reversed to move the panel or slip-sheet from the special panel holder 1450 to the untrimmed panel holder 1420, the trimmed panel holder 1430, and the panel fixture 510.

Again, although not shown in FIG. 14, beneficially the remainder of the trimming system including panel fixture, X-Y stage, laser, probe assembly and controller is also enclosed by an enclosure containing a door which can be opened from the front of the trim system by the operator to insert or remove a single panel at the panel fixture 510. Hence, the embodiment of FIG. 14 provides a front loading trim system into which either a single panel can be inserted directly onto the panel fixture by the operator for trimming or into which multiple panels can be inserted into a holder by the operator and automatically loaded on and removed from the panel fixture by a panel handler under the control of the controller.

FIG. 15 depicts a seventh embodiment of the handler assembly 570 of FIG. 5. The FIG. 15 handler assembly is similar to that of FIG. 8, but with the addition of an automated panel holder exchange means disposed behind the side by side panel holders.

In FIG. 15, the assembly 570 includes all of the components described in the preferred embodiment depicted in FIG. 8. Additionally, the assembly contains a vertical panel holder magazine 1510 located to the rear of the untrimmed and trimmed panel holder locations. This magazine serves to automate the placement into the handler assembly and removal from the handler of the untrimmed and trimmed panel holders respectively.

Operation of the handler depicted in FIG. 15 is similar to that of the preferred embodiment depicted in FIG. 8, with the modification and addition of two sequences. Prior to automated operation, full untrimmed panel holders 1520 are loaded by the operator on the magazine in their respective positions at the rear of the handler assembly. Similarly, empty trimmed panel holders 1530 are loaded by the operator on the magazine in their respective positions at the rear of the handler assembly. The first untrimmed and trimmed panel holders are moved into the untrimmed and trimmed panel storage locations by the controller 550, and the trimming sequence commences.

Once all of the panels originally in the untrimmed panel holder have been trimmed and transferred to the trimmed panel holder, the two holders are moved back into the magazine, the magazine is indexed to the next set of panel holders, and this new set of panel holders is moved into the untrimmed and trimmed panel storage locations by the controller 550. Again, the trimming sequence commences.

Alternatively, the full trimmed panel holder is moved back into its magazine and replaced by a new full untrimmed panel holder from the magazine. The untrimmed panel holder from the previous processing sequence, which is now empty, assumes the role of the trimmed panel holder. Again, the trimming sequence commences with the positions of the untrimmed panel holder 1520 and the trimmed panel holder 1530 exchanged.

In routine operation, this cycle is repeated until all of the untrimmed panel holders in the magazine have been emptied, all of the panels have been trimmed, and all of the panels are located in the trimmed panel holders in the magazine. With reference to FIG. 15, the operator may also be permitted to remove from the magazine and/or place into the magazine trimmed and/or untrimmed panel holders during operation of the system. This capability has the advantage of allowing the automated trimming system to run continuously and without interruption even when trimmed panels are being removed and untrimmed panels are being placed into the handler assembly. It should also be noted that the time interval between loading and unloading of the panel holders from the magazine can be much longer due to the higher number of panels being trimmed within the automated trimming system.

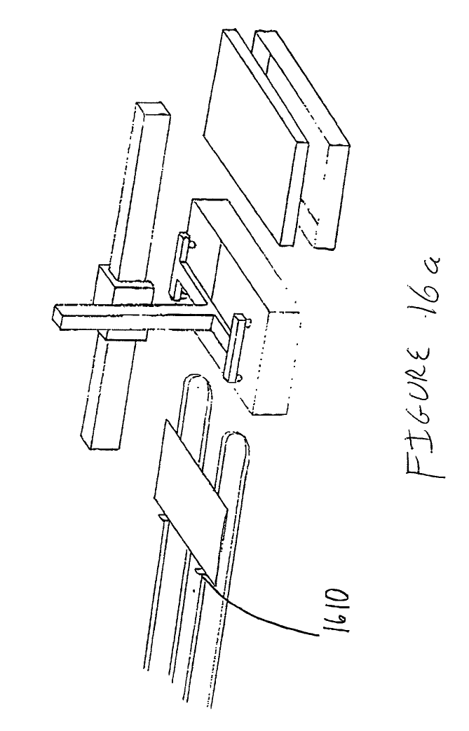

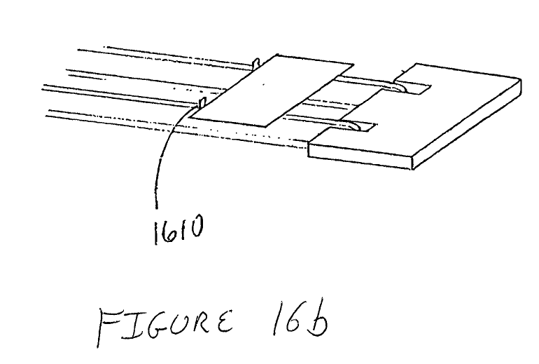

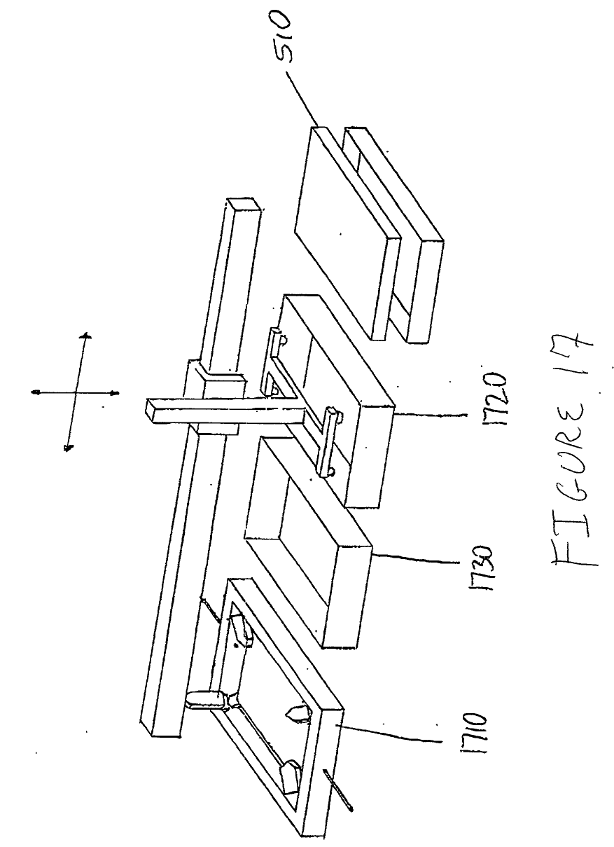

FIG. 16a depicts an eighth embodiment of the handler assembly 570 of FIG. 5. The FIG. 16a handler assembly is similar to that of FIG. 8, but with the substitution of a conveyor in place of the untrimmed panel holder.

In FIG. 16a, the assembly 570 includes all of the components described in the preferred embodiment depicted in FIG. 8, except the untrimmed panel holder. Instead, the assembly contains a conveyor 1610 that terminates at the untrimmed panel storage location.

Operation of the handler depicted in FIG. 16a is similar to that of the preferred embodiment depicted in FIG. 8, with the modification that the conveyor 1610 is operated either through the controller 550 or through means external to the automated trimming system to provide a panel or stack of panels at the untrimmed panel storage location when required for trimming.

In routine operation, the conveyor 1610 would typically be controlled to provide a panel for trimming at appropriate time intervals such that the trimming system was able to run continuously and without interruption.

This capability has the advantage of allowing the automated trimming system to be integrated into conventional conveyor handling systems common in PCB manufacturing facilities. It should also be noted that the requirement for operator attention to the automated trimming system is reduced to that of unloading full trimmed panel holders from the system.

FIG. 16b depicts a ninth embodiment of the handler assembly 570 of FIG. 5. The FIG. 16b handler assembly departs significantly from the embodiment depicted in FIG. 8, with the substitution of a conveyor for the entire panel handler assembly.

In FIG. 16b, the assembly 570 includes only a conveyor 1610 that terminates at the panel fixture 510 load/unload location 1610.

Operation of the handler depicted in FIG. 16b is similar to that of the embodiment depicted in FIG. 16a, with the modification that the conveyor 1610 places an untrimmed panel directly onto, and removes a trimmed panel directly from, the panel fixture 510. The conveyor 1610 is operated, either through the controller 550 or through means external to the automated trimming system, to provide a single panel at the panel fixture 510 load/unload location when required for trimming. The conveyor 1610 is also operated, either through the controller 550 or through means external to the automated trimming system, to remove a single panel from the panel fixture 510 load/unload location once trimming of the panel is complete.

In routine operation, the conveyor 1610 would typically be controlled to provide a panel for trimming at appropriate time intervals, and similarly remove a panel after trimming at appropriate time intervals, such that the trimming system was able to run continuously and without interruption.

This capability has the advantage of allowing the automated trimming system to be integrated into conventional conveyor handling systems common in PCB manufacturing facilities. It should also be noted that the requirement for operator attention to the automated trimming system is much reduced since there is no requirement for loading untrimmed panel holders or unloading trimmed panel holders from the system.

FIG. 17 depicts a tenth embodiment of the handler assembly 570 of FIG. 5. The FIG. 17 handler assembly is similar to that of FIG. 8, but with the addition of an automated panel flipping means disposed in line with the side by side panel holders.

In FIG. 17, the assembly 570 includes all of the components described in the preferred embodiment depicted in FIG. 8. Additionally, the assembly contains a panel flipper module 1710 located beside the untrimmed and trimmed panel holder locations. This flipper module serves to automate the flipping of panel top sides as placed on the panel fixture 510. In some applications, panels may contain untrimmed circuit elements disposed on both top and bottom panel surfaces. All of the previous embodiments describe a handler sequence where the panels transferred from the untrimmed panel storage location, through the trimming operation, and then to the trimmed panel storage location, remain in the same orientation.

Operation of the handler depicted in FIG. 17 is similar to that of the preferred embodiment depicted in FIG. 8, with the modification and addition of two sequences. Transfer of a trimmed panel from the panel fixture 510 to the trimmed panel storage location after trimming is accomplished in three additional steps. The panel is first removed from the panel fixture 510 using the panel pick-up head and lifter as described previously. The panel is next placed on the flipper module 1710 located in line with the panel holders. The flipper module is instructed by the controller 550 to flip the panel such that the bottom side of the panel is now the top side. The panel pick-up head and lifter then move the panel from the flipper module to the trimmed panel holder 1730.

Application of this sequence to all of the panels during automated trimming results in the trimmed panel holder containing all of the panels trimmed on their top sides stored upside down. If the panels located in the trimmed panel holder bottom side up require trimming on the bottom side, then, as described previously, further operation of the handler assembly in a bottom side trimming sequence is now possible simply by switching the respective definitions for the locations of the two holders 1720 and 1730 in the handler assembly at the controller 550.

The panels located in the trimmed panel holder are then one by one loaded onto the panel fixture 510 using the pick-up head, lifter, and gantry, trimmed, and unloaded into the original untrimmed panel holder. At the conclusion of this bottom side trimming sequence, the original untrimmed panel holder would contain all of the panels trimmed on both sides.

The sequence above is also fully compatible with the previously described slip-sheet transfer.

It should be noted that this method provides for reduced handling of the panels and panel holders by the operator, since both side trimming sequences are conducted automatically by the trimming system. It should also be noted that the time interval between loading and unloading of the panel holders from the system can be much longer due to the higher number of panel sides being trimmed within the automated trimming system. It should further be noted that this method provides the operator a means for quick reloading of the automated trimming system by exchanging only a single holder the untrimmed panel holder.

System Operation Sequence

According to a preferred sequence of steps for trimming a panel 540 according to the best mode of the invention, and referring to FIG. 5a stack of untrimmed panels 540 is loaded into a first panel holder 720 and the panel holder 720 is loaded into a position adjacent to the panel fixture 510. The untrimmed panels 540 are loaded into the panel holder 720 with the side to be trimmed facing up. In addition, a second, empty panel holder 730 is loaded into a position adjacent to the first panel holder 720. The first and second panel holder positions are each under the travel of the gantry 830. With the full and empty panel holder 720/730 in place, an operator inputs commands to the system via the input device 559 to instruct the system controller 550 to select the appropriate panel trimming job program and to initiate a trimming job sequence in accordance with the panel type loaded into the panel holder 720. In addition, to these steps, the operator may have installed one or more probe cards 560, in accordance with the panel type loaded into the panel holder 720 and closed any doors of the system 500 before initiating an automatic trimming operation.

In a first automatic sequence of steps, the X-Y stage is moved to a load position for receiving an untrimmed panel 540 onto the panel fixture 510. In FIG. 5, the fixture 510 is moved to the left along the X-axis to receive a panel 540 from the panel picker 740 mounted onto the gantry and rail 823. To pick a panel from the panel holder 720, the panel picker 740 is moved to a pick position over the stack of untrimmed panels in the panel holder 720. Next the panel picker 740 attaches to a slip-sheet over the top most panel in the stack, if a slip-sheet is present. A slip-sheet detector device, not shown, may also be provided to detect the presence of a slip-sheet on top of the stack. Once a slip-sheet is attached, the gantry 830 advances the panel handler 740 with the slip-sheet attached to a plate picking position over the empty panel holder 730 and deposits the slip-sheet in the bottom of the empty panel holder 730. Alternately, the slip-sheet may be otherwise disposed. The gantry 830 then returns the panel handler 740 to the panel picking position above the first panel holder 720. The panel handler 740 then picks the top panel 540 in the panel holder 720 and lifts the panel upward without bending the panel or damaging the surface of the panel to be trimmed.

The gantry 830 then advances the panel handler 740 to a panel loading position above the panel fixture 510. The panel handler 740 then lowers the panel 540 onto the panel fixture 510. In accordance with the invention, prior to loading the panel 540, the X-Y stage 542 positions the panel fixture 510 in both the X and Y direction to place the panel fixture 510 in a load position which may receive a panel 540 with two edges positioned in a substantially known position with respect to the panel fixture 510. Upon receiving the panel 540, the panel fixture 510 may clamp the panel 540 in a fixed position using a vacuum platen, mechanical clamp or any other suitable clamping device. The system controller 550 may then begin a sequence of steps for determining a position and orientation of the panel on the panel fixture using the video camera system 552 or other position detecting means. Once the panel orientation is acquired, a selected portion of the panel 540 may then be positioned under the lens 520 for trimming. Thereafter, the entire panel is trimmed through a series of panel movements and trim steps until the trimming is completed.

Simultaneously with the steps for positioning and trimming the panel 540, the panel handler 740 may be moved from the panel loading position to the panel pick up position above the first panel holder 720. The panel picker 740 may then pick up the next slip-sheet in the stack and move the slip-sheet to the second panel holder 730. Thereafter, the panel picker 740 may be moved to the panel loading position next to the panel fixture 510 to await the completion of the panel being trimmed.

Once the panel 540 is completely trimmed, the panel fixture 510 is once again moved to a position under the panel handler 740 and the finished panel is picked up from the panel fixture 510 by the panel handler and advanced to the second panel holder 730 by the gantry 830. The finished panel is then lowered into the second panel holder 730 which will hold the entire stack of trimmed panels at the end of the operation.

After removing the finished panel, the panel handler 740 is advanced to the first panel holder 720 to pick up a second panel for delivery to the panel fixture 510. After installing the second panel onto the panel fixture, the panel handler 740 returns to move the slip-sheet on top of the next panel in the first panel holder 720 to the top of the finished panel in the second panel holder 730. Before picking each new panel from the first panel holder 720 a determination is made by the system controller 550 as to whether or not additional untrimmed panels stored in the untrimmed panel storage location require trimming. If so the operations continue. If not the operations stop. It should be understood that stopping operations could include other steps, such as moving the stage to a parked position. To determine whether further panels need to be trimmed, a panel detector may be provided or a panel counter may be used to count a predetermined number of panels in a sequence.

Additionally, there may exist conditions during fabrication where special consideration for a particular panel is desired. The reasons for this special consideration include, but are not limited to, an abnormal condition encountered during trimming, a defect in the panel, a defect with the trimming or measurement results, separation of the panel for inspection, etc. For this purpose, a special panel storage location is provided within the automated trimming system.

Thus the trim system may include an untrimmed panel storage location, a trimmed panel storage location, a special panel storage location, and a panel handler for moving the panels and/or slip-sheets between the untrimmed panel storage location, the trimmed panel storage location, the special panel storage location, and the panel fixture 510 as necessary during operation.

As noted above, the trimming system 500 of FIG. 5 includes a panel handler assembly 570, which operates in accordance with handler control signals issued by the controller 550 to perform the above described storage, slip-sheet removal, and loading and unloading of the work pieces onto and off of the panel fixture 510.

I/we claim:

1. An automated method for trimming a circuit element disposed on a substrate, comprising:
transmitting a first signal to move a substrate, having a circuit element disposed thereon, to a trimming location; and
transmitting a second signal to emit a light beam, with the substrate at the trimming location, to trim the circuit element.

2. An automated method according to claim 1, further comprising:
transmitting a third signal to move the substrate, with the trimmed circuit element, from the trimming location to a storage location.

3. An automated method according to claim 1, further comprising:
storing the substrate at a storage location prior to removing material from the circuit element;
wherein the first signal is transmitted to move the substrate from the first storage location to the trimming location.

4. An automated method according to claim 3, further comprising:
storing, at the storage location, a slip sheet on top of the substrate; and
transmitting a third signal to move the slip sheet from the storage location.

5. An automated method according to claim 4, wherein:
the storage location is a first storage location;
the third signal is transmitted to move the slip sheet from the first storage location to a second storage location; and
the substrate is moved from the first storage location to the trimming location after the slip sheet is moved from the first storage location to the second storage location.

6. An automated method according to claim 5, wherein the substrate is a first substrate and the circuit element is a first circuit element, and further comprising:
transmitting a fourth signal to emit the light beam, with a second substrate, having a second circuit element, at the trimming location, to trim the second circuit element, and with the slip sheet being moved from the first storage location to the second storage location;
transmitting a fifth signal, with the slip sheet at the second storage location, to move the second substrate, with the trimmed second circuit element, from the trimming location to the second storage location;
wherein the first substrate is moved from the first storage location to the trimming location after the second substrate is moved from the trimming location to the second storage location.

7. An automated method according to claim 1, further comprising:
transmitting a third signal to adjust a positional relationship between the substrate at the trimming location and a path of the emitted beam, such that the circuit element in a field of view.

8. An automated method according to claim 1, further comprising:
transmitting a third signal to adjust a path of the emitted light beam with the substrate at the trimming location, to trim the circuit element.

9. An automated method according to claim 1, further comprising:
transmitting a third signal to measure an electrical characteristic of the trimmed circuit element and with the substrate at the trimming location.

10. An automated method according to claim 9, further comprising:
transmitting a fourth signal to move the substrate, with the trimmed circuit element, from the trimming location to one of a first storage location and a second storage location;
wherein the substrate is moved from the trimming location to the first storage location if the measured electrical characteristic is within a threshold;
wherein the substrate is moved from the trimming location to the second storage location if the measured electrical characteristic is outside the threshold.

11. An automated method according to claim 9, further comprising:
destroying or marking the circuit element with the emitted beam if the measured electrical characteristic is outside a threshold.

12. An automated system for trimming a circuit element disposed on a substrate, comprising:
a moveable pick-up device configured to pick-up a substrate, having a circuit element disposed thereon, and to move the picked-up substrate to a trimming location; and
an emitter configured to emit a light beam, with the substrate at the trimming location, to trim the circuit element.

13. An automated system according to claim 12, wherein:
the moveable pick-up device is further configured to pick-up the substrate, with the trimmed circuit element, at the trimming location, and to move the picked-up substrate to a storage location.

14. An automated system according to claim 12, further comprising:
a first holder configured to store the substrate prior to trimming the circuit element;
wherein the moveable pick-up device is further configured to pick-up the substrate from the first holder and to move the picked-up substrate to the trimming location.

15. An automated system according to claim 14, wherein:
the first holder is further configured to store a slip sheet on top of the substrate; and
the moveable pick-up device is further configured to pick-up the slip sheet from the first holder.

16. An automated system according to claim 15, further comprising:
a second holder configured to store the substrate subsequent to trimming the circuit element;
wherein the moveable pick-up device is further configured to move the picked-up slip sheet to the second holder;
wherein the moveable pick-up device is further configured to move the substrate to the trimming location after the picked-up slip sheet is moved to the second holder.

17. An automated system according to claim 16, wherein:
the substrate is a first substrate and the circuit element is a first circuit element;
the emitter is further configured to emit the light beam, with a second substrate, having a second circuit element, at the trimming location and with moveable pick-up device moving the slip sheet to the second holder, to remove material from the second circuit element;
with the slip sheet moved to the second holder, the moveable pick-up device is further configured to pick-up the second substrate, with the trimmed second circuit element, from the trimming location and to move the picked-up second substrate to the second holder;
the moveable pick-up device is further configured to pick-up the first substrate from the first holder and to move the picked-up first substrate to the trimming location, after the second substrate is picked-up from the trimming location and moved to the second holder.

18. An automated system according to claim 12, further comprising:
a moveable stage configured to adjust a positional relationship between the substrate at the trimming location and a path of the emitted light such that the circuit element is in a field of view beam prior to emitting the light beam.

19. An automated system according to claim 12, wherein:
the emitter is further configured to adjust a path of the emitted light beam with the substrate at the trimming location, to trim the circuit element.

20. An automated system according to claim 12, further comprising:
a probe configured to measure an electrical characteristic of the trimmed circuit element with the substrate at the trimming location.

21. An automated system according to claim 20, wherein:
the moveable pick-up device is further configured to move the substrate, with the trimmed circuit element, from the trimming location to a first holder if the measured electrical characteristic is within a threshold and to a second holder if the measured electrical characteristic is outside the threshold.

22. An automated system according to claim 12, wherein:
the substrate is a panel.

23. An automated system according to claim 12, wherein:
the emitter includes a laser and a focusing lens.

24. An automated system according to claim 12, further comprising:
a first cassette holder configured to store the substrate prior to being picked-up by the moveable pick-up device; and
a second cassette holder configured to store the substrate with the trimmed circuit element;
wherein the moveable pick-up device is further configured to pick-up the substrate, having a circuit element disposed thereon, from the first cassette holder, and to pick-up the substrate with the trimmed circuit element at the trimming location and to move the picked up substrate to the second cassette holder.

25. An automated system according to claim 24, further comprising:
a housing configured to house the first cassette holder and the second cassette holder;
wherein the first and the second cassette holders are removable from a same side of the housing.

26. An automated system according to claim 25, wherein:
the housing includes a hinged door on the same side of the housing; and
at least one of the first and the second cassette holders is accessible for removal by opening the hinged door.

27. An automated system according to claim 26, wherein:
the same side is a front side of the housing;
the first and the second cassette holders are positioned at the same elevation and disposed side by side when viewed from the front side of the housing;
the hinged door is a first hinged door;
the housing includes a second hinged door on the front side of the housing;
the first holder is accessible for removal by opening the first hinged door; and
the second holder is accessible for removal by opening the second hinged door.

28. An automated system according to claim 25, wherein:
the trimming location is accessible from the same side of the housing to manually place another substrate having a circuit element at the trimming location and to manually remove the other substrate after completion of the trimming from the trimming location.

29. An automated system according to claim 24, further comprising:
a housing configured to house the first cassette holder and the second cassette holder;
wherein the first and the second holders are removable from different sides of the housing.

30. A system according to claim 29, wherein:
the different sides include a front side of the housing;
the housing includes a rear side opposed to the front side;
the first cassette holder is at the same elevation as the second cassette holder, and is disposed adjacent to the second cassette holder and proximate to the front side of the housing; and
the second cassette holder is disposed proximate to the rear side of the housing.

31. An automated system according to claim 24, further comprising:
a housing configured to house the first cassette holder and the second cassette holder;
wherein the first and the second cassette holders are removable from a side of the housing;
wherein the housing includes a hinged door on the side of the housing and the first and the second cassette holders are accessible for removal by opening the hinged door.
